(19) United States
(12) Patent Application Publication
(10) Pub. No.: US 2025/0142834 A1
(43) Pub. Date: May 1, 2025

(54) SEMICONDUCTOR DEVICE AND ELECTRONIC SYSTEM INCLUDING SEMICONDUCTOR DEVICE

(71) Applicant: SAMSUNG ELECTRONICS CO., LTD., SUWON-SI (KR)

(72) Inventors: Suseong Noh, Suwon-si (KR); Ilho Myeong, Suwon-si (KR); KWANG-SOO KIM, Suwon-si (KR)

(21) Appl. No.: 18/732,268

(22) Filed: Jun. 3, 2024

(30) Foreign Application Priority Data
Oct. 27, 2023 (KR) 10-2023-0145952

(51) Int. Cl. H10B 51/30; H10B 51/20

(52) U.S. Cl. CPC H10B 51/30; H10B 51/20

(57) ABSTRACT

A semiconductor device includes: a substrate; a gate stacking structure that includes interlayer insulating layers and gate electrodes that are alternately stacked on the substrate; a channel structure that penetrates the gate stacking structure and extends in a first direction, and includes a channel layer connected to the substrate and a ferroelectric layer that surrounds the channel layer; a charge inflow pattern disposed on a lateral side of the ferroelectric layer and spaced apart in the first direction; and an insulation pattern disposed between the charge inflow pattern and the gate electrodes and that surrounds an exterior side, a lower side, and an upper side of the charge inflow pattern.

### CROSS-REFERENCE TO RELATED APPLICATION

This application claims priority under 35 U.S.C. 119 from Korean Patent Application No. 10-2023-0145952, filed in the Korean Intellectual Property Office on Oct. 27, 2023, the contents of which are herein incorporated by reference in their entirety.

### TECHNICAL FIELD

Embodiments of the present disclosure are directed to a semiconductor device and a manufacturing method thereof, and an electronic system that includes the semiconductor device.

### DISCUSSION OF THE RELATED ART

Semiconductor memory devices may be classified into volatile memory devices and nonvolatile memory devices. In a volatile memory device, stored data disappears when power supply is interrupted, such as in a dynamic random access memory (DRAM) and a static random access memory (SRAM). In a nonvolatile memory device, stored data are not destroyed even if the power supply is interrupted, such as in a programmable ROM (PROM), an erasable PROM (EPROM), an electrically EPROM (EEPROM), a flash memory device, etc. In addition, next generation nonvolatile semiconductor memory devices that have higher performance and lower power consumption, such as a magnetic random access memory (MRAM), a phase-change random access memory (PRAM), and a ferroelectric random access memory (FeRAM), are being developed.

### SUMMARY

Embodiments of the present disclosure provide a semiconductor device that increases reliability and a data storage system that includes the same.

An embodiment of the present disclosure provides a semiconductor device that includes: a substrate; a gate stacking structure that includes interlayer insulating layers and gate electrodes that are alternately stacked on the substrate; a channel structure that penetrates the gate stacking structure and extends in a first direction, and includes a channel layer connected to the substrate and a ferroelectric layer that surrounds the channel layer; a charge inflow pattern disposed on a lateral side of the ferroelectric layer and spaced apart in the first direction; and an insulation pattern disposed between the charge inflow pattern and the gate electrodes and that surrounds an exterior side, a lower side, and an upper side of the charge inflow pattern.

Another embodiment of the present disclosure provides a semiconductor device that includes: a substrate; a gate stacking structure that includes interlayer insulating layers and gate electrodes that are alternately stacked on the substrate; a channel structure that penetrates the gate stacking structure and extends in a first direction, and includes a channel layer connected to the substrate and a ferroelectric layer that surrounds the channel layer; a charge inflow pattern disposed between the ferroelectric layer and the gate electrodes; and an insulation pattern disposed between the charge inflow pattern and the gate electrodes and between the charge inflow pattern and the interlayer insulating layers, and into which nitrogen is doped. A concentration of nitrogen in at least a portion of the insulation pattern decreases with increasing distance from the charge inflow pattern.

Another embodiment of the present disclosure provides an electronic system that includes: a main substrate; a semiconductor device disposed on the main substrate; and a controller electrically connected to the semiconductor device on the main substrate. The semiconductor device includes a peripheral circuit region, a cell region that includes an input/output connecting wire that is electrically connected to the peripheral circuit region, and an input/output pad that is electrically connected to the input/output connecting wire that extends into the cell region. The cell region includes a substrate, a gate stacking structure that includes interlayer insulating layers and gate electrodes that are alternately stacked on the substrate, a channel structure that penetrates the gate stacking structure and extends in the first direction, and includes a channel layer connected to the substrate and a ferroelectric layer that surrounds the channel layer, a charge inflow pattern disposed on a lateral side of the ferroelectric layer and spaced apart in the first direction, and an insulation pattern disposed between the charge inflow pattern and the gate electrodes and surrounding an exterior side, a lower side, and an upper side of the charge inflow pattern.

### BRIEF DESCRIPTION OF THE DRAWINGS

FIG. 1 and FIG. 2 are cross-sectional views of a semiconductor device according to an embodiment.

FIG. 3 and FIG. 4 are cross-sectional views of various examples of a channel structure of a semiconductor device of in FIG. 1.

FIG. 5 is an enlarged cross-sectional view of a region S1 of FIG. 2.

FIG. 6 is a graph of dopant concentration of an insulation pattern according to an embodiment.

FIG. 7 is a graph of dopant concentration of an insulation pattern according to several embodiments.

FIG. 8 to FIG. 14 are cross-sectional views on a region S1 of a semiconductor device of FIG. 2 according to several embodiments.

FIG. 15 is a cross-sectional view of a semiconductor device according to several embodiments.

FIG. 16 and FIG. 17 are cross-sectional views that illustrate intermediate stages of a method for manufacturing a semiconductor device according to an embodiment.

FIG. 18 to FIG. 24 are cross-sectional views of a region S2 of FIG. 17 that illustrate a method for manufacturing a semiconductor device according to an embodiment.

FIG. 25 shows an electronic system that includes a semiconductor device according to an embodiment.

FIG. 26 is a perspective view of an electronic system that includes a semiconductor device according to an embodiment.

FIG. 27 and FIG. 28 are cross-sectional views of a semiconductor package according to an embodiment.

### DETAILED DESCRIPTION

Embodiments of the present disclosure will be described more fully hereinafter with reference to the accompanying drawings, in which embodiments of the disclosure are shown. As those skilled in the art would realize, the described embodiments may be modified in various different ways, all without departing from the spirit or scope of the present embodiment.

In the drawings, the same elements may be designated by the same reference numerals throughout the specification.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

The phrase “in a plan view” means viewing an object portion from the top, and the phrase “in a cross-sectional view” means viewing a cross-section of which the object portion is vertically cut from the side.

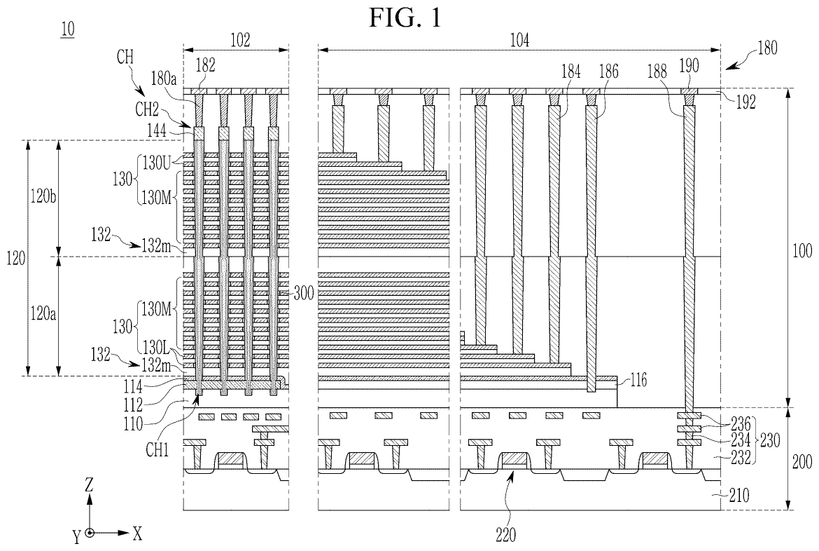

A semiconductor device according to an embodiment will now be described with reference to FIG. 1 to FIG. 7.

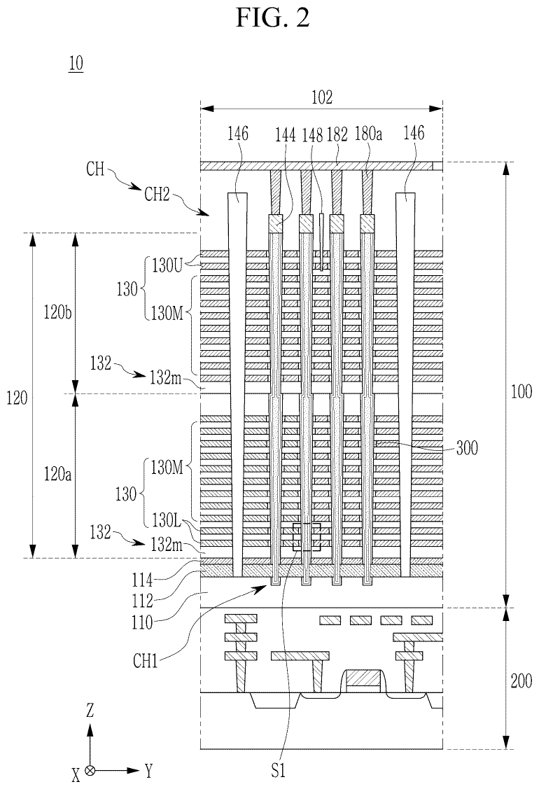

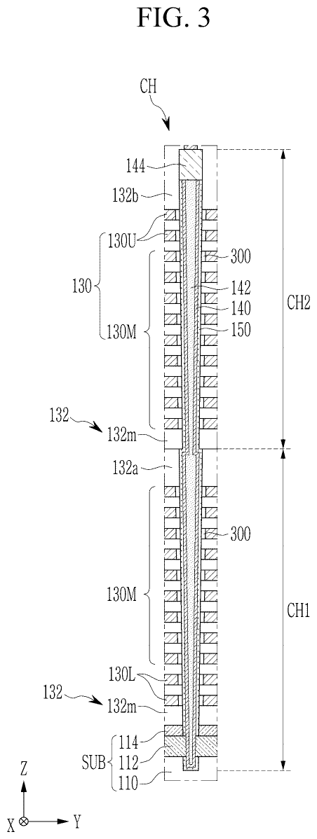

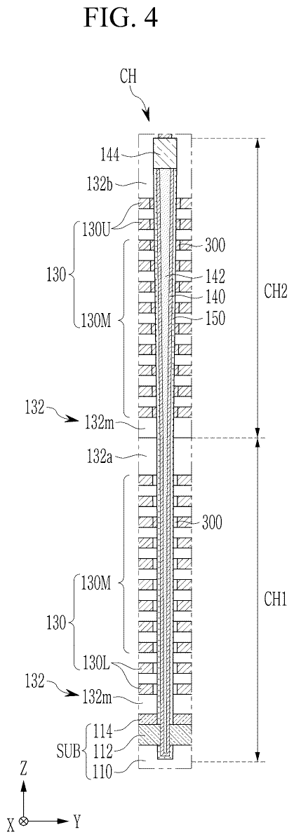

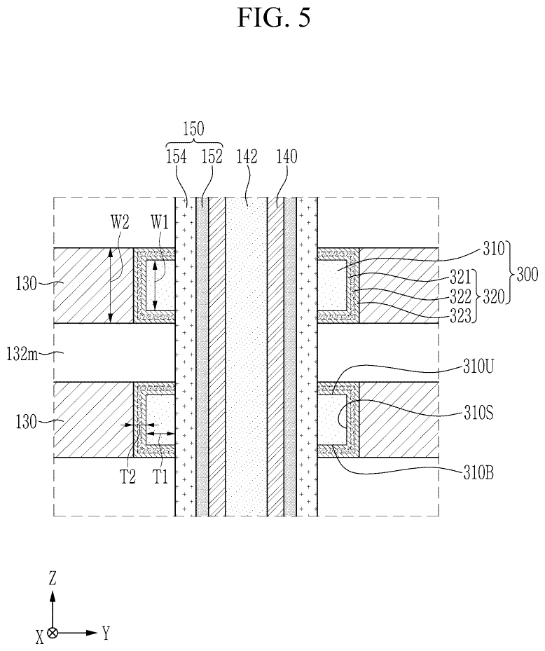

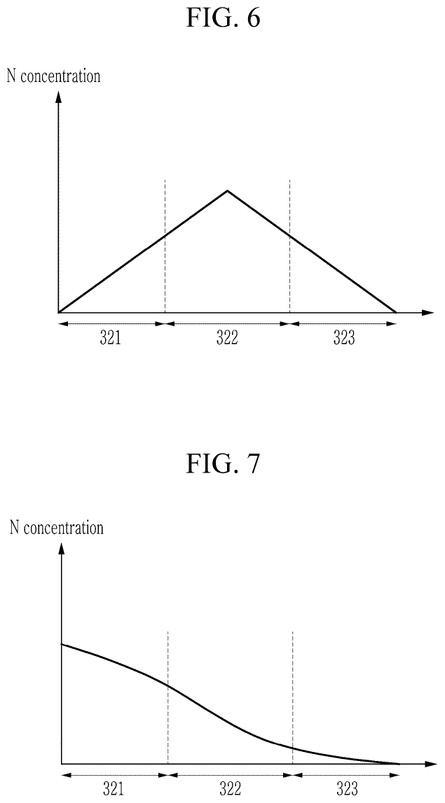

FIG. 1 and FIG. 2 are cross-sectional views of a semiconductor device according to an embodiment. FIG. 3 and FIG. 4 are cross-sectional views of various examples of a channel structure in a semiconductor device shown in FIG. 1. FIG. 5 is an enlarged cross-sectional view of a region S1 of FIG. 2. FIG. 6 is a graph of dopant concentration of an insulation pattern according to an embodiment. FIG. 7 is a graph of dopant concentration of an insulation pattern according to several embodiments.

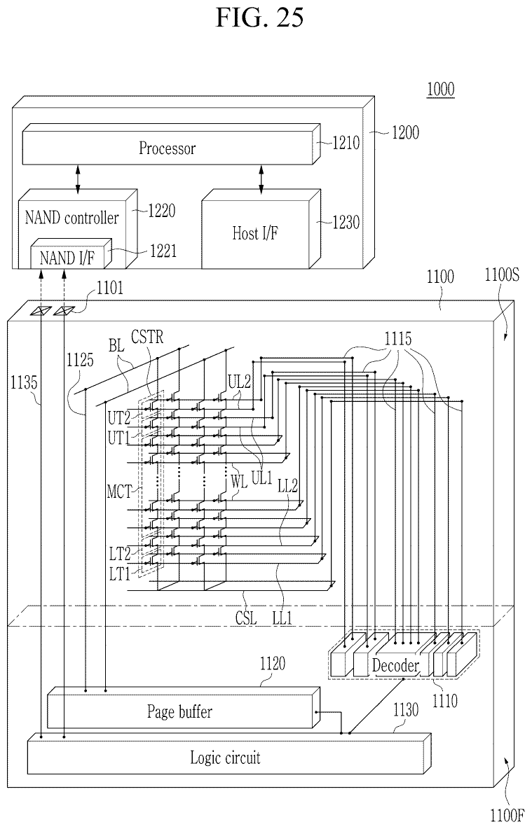

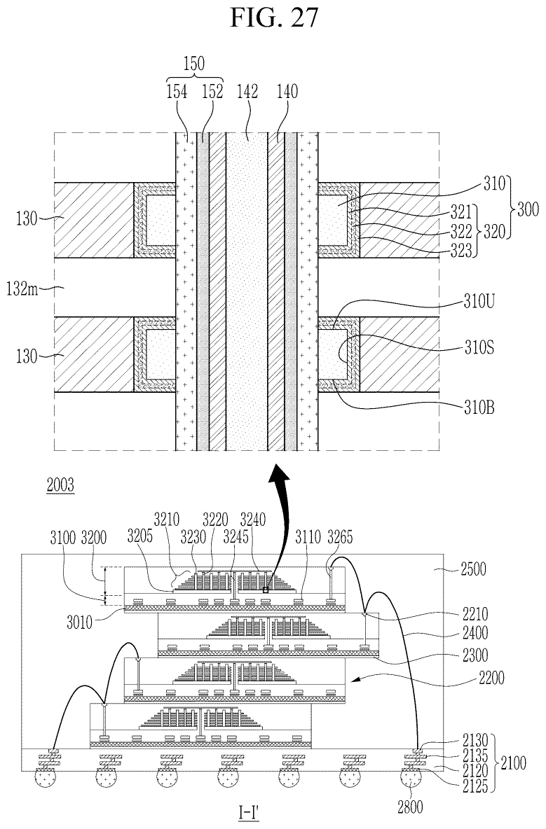

Referring to FIG. 1 and FIG. 2, in an embodiment, the semiconductor device 10 includes a cell region 100 that includes a memory cell structure, and a circuit region 200 that includes a peripheral circuit structure that controls an operation of the memory cell structure. For example, the circuit region 200 and the cell region 100 correspond to a first structure 1100F and a second structure 1100S of a semiconductor device 1100 of an electronic system 1000 shown in FIG. 25. For example, the circuit region 200 and the cell region 100 correspond to a first structure 3100 and a second structure 3200 of a semiconductor chip 2200 shown in FIG. 27.

The circuit region 200 includes the peripheral circuit structure disposed on a first substrate 210, and the cell region 100 includes a gate stacking structure 120 and a channel structure CH disposed on a second substrate 110 in a cell array region 102 as the memory cell structure. A first wire portion 230 that is electrically connected to the peripheral circuit structure is disposed in the circuit region 200, and a second wire portion 180 that is electrically connected to the memory cell structure is disposed in the cell region 100.

In an embodiment, the cell region 100 is disposed on the circuit region 200. According to this, an area that corresponds to the circuit region 200 does not need to be secured separately from cell region 100 so that an area of the semiconductor device 10 can be reduced. However, embodiments are not necessarily limited thereto, and in some embodiments, the circuit region 200 is disposed near the cell region 100. Various other changes are possible.

The circuit region 200 includes the first substrate 210, and a circuit element 220, and the first wire portion 230 disposed on the first substrate 210.

The first substrate 210 includes a semiconductor material. For example, the first substrate 210 may be made of a semiconductor material, or may be a semiconductor substrate with a semiconductor layer formed on a base substrate. For example, the first substrate 210 is made of one of silicon, epitaxial silicon, germanium, silicon-germanium, a silicon-on-insulator (SOI), or a germanium-on-insulator (GOI).

The circuit element 220 formed on the first substrate 210 includes various circuit elements that control the operation of the memory cell structure in the cell region 100. For example, the circuit element 220 constitutes a peripheral circuit structure such as a decoder circuit 1110 in FIG. 25, a page buffer 1120 in FIG. 25, or a logic circuit 1130 in FIG. 25.

The circuit element 220 includes, for example, a transistor, but is not necessarily limited thereto. For example, the peripheral circuit element 220 includes active elements such as a transistor, as well as passive elements such as a capacitor, a resistor, and/or an inductor.

The first wire portion 230 disposed on the first substrate 210 is electrically connected to the circuit element 220. In an embodiment, the first wire portion 230 includes wiring layers 236 spaced apart with a first insulation layer 232 therebetween and connected to form a desired path by a contact via 234. The wiring layer 236 or the contact via 234 include various conductive materials, and the first insulation layer 232 includes various insulating materials.

The cell region 100 of the semiconductor device 10 includes the second substrate 110, the gate stacking structure 120, the channel structure CH, a gate dielectric pattern 300, a separation structure 146, and a gate contact portion 184.

The second substrate 110 includes the cell array region 102 and a contact region 104. The gate stacking structure 120 and the channel structure CH are disposed on the second substrate 110 in the cell array region 102. The gate stacking structure 120, the gate contact portion 184 that connects the gate stacking structure 120 of the cell array region 102 to the circuit region 200 or an external circuit, and/or a structure that connects the channel structure CH to the circuit region 200 or the external circuit are disposed on the second substrate 110 in the contact region 104.

At least a portion of the first insulation layer 232 is disposed between the second substrate 110 and the first wire portion 230. A portion of the first insulation layer 232 disposed between the second substrate 110 and the first wire portion 230 may have a single layer or a multilayer structure. For example, a layer that includes silicon nitride and a layer that includes silicon oxide is disposed between the second substrate 110 and the first wire portion 230. For example, the layer that includes silicon oxide is disposed on the layer that includes silicon nitride.

The gate stacking structure 120 includes a cell insulation layer 132 and gate electrodes 130 alternately stacked on a first side, such as a front side or an upper side, of the second substrate 110, and the channel structure CH penetrates the gate stacking structure 120 and extends in a direction, such as the third direction or Z direction, that crosses the second substrate 110, and is disposed in the cell array region 102.

The second substrate 110 includes a semiconductor material, such as polysilicon. For example, the second substrate 110 includes polysilicon doped with impurities. However, without being necessarily limited thereto, for example, the second substrate 110 includes a metallic material or a metal silicide.

The semiconductor device 10 further includes a first horizontal conductive layer 112 and a second horizontal conductive layer 114.

The first horizontal conductive layer 112 is disposed on the second substrate 110 in the cell array region 102. The first horizontal conductive layer 112 electrically connects the channel structure CH and the second substrate 110. The first horizontal conductive layer 112 is a portion of a common source line, such as CSL of FIG. 25, of the semiconductor device 10. For example, the first horizontal conductive layer 112 functions as a common source line together with the second substrate 110.

The first horizontal conductive layer 112 is penetrated by the channel structure CH. For example, a ferroelectric layer 154 and a channel insulation layer 152 of the channel structure CH are removed from a portion where the first horizontal conductive layer 112 is disposed, and the first horizontal conductive layer 112 is connected to a channel layer 140. For example, the first horizontal conductive layer 112 directly contacts the channel layer 140. Hence, the first horizontal conductive layer 112 electrically connects the second substrate 110 and the channel layer 140.

Further, the first horizontal conductive layer 112 is not disposed between the second substrate 110 and the gate stacking structure 120 in a region of the contact region 104. For example, a horizontal insulation layer 116 is disposed between the second substrate 110 and the gate stacking structure 120. The horizontal insulation layer 116 includes one or more of various types of insulating materials. For example, the horizontal insulation layer 116 includes a silicon oxide (SiO₂) and/or a silicon nitride (SiN). The horizontal insulation layer 116 remains in the region of the contact region 104 during a replacement process that forms the first horizontal conductive layer 112. The horizontal insulation layer 116 may have a multilayer structure, but is not necessarily limited thereto.

The second horizontal conductive layer 114 is disposed on the first horizontal conductive layer 112 and the horizontal insulation layer 116. The second horizontal conductive layer 114 extends in a first direction (X direction) and a second direction (Y direction) in the cell array region 102 and the contact region 104. The second horizontal conductive layer 114 electrically connects the channel structure CH and the second substrate 110 together with the first horizontal conductive layer 112. The second horizontal conductive layer 114 is a portion of the common source line of the semiconductor device 10. The second horizontal conductive layer 114 is penetrated by the channel structure CH.

The second horizontal conductive layer 114 is a support layer that prevents a mold stack from being destroyed or collapsing in the replacement process that forms the first horizontal conductive layer 112.

The first and second horizontal conductive layers 112 and 114 include semiconductor materials, such as polysilicon. For example, the first horizontal conductive layer 112 includes polysilicon doped with impurities, and the second horizontal conductive layer 114 includes polysilicon doped with impurities, or includes impurities diffused from the first horizontal conductive layer 112. However, embodiments are not necessarily limited thereto, and in some embodiments, the second horizontal conductive layer 114 includes an insulating material. In some embodiments, the second horizontal conductive layer 114 is omitted.

The gate stacking structure 120 in which the cell insulation layer 132 and the gate electrodes 130 are alternately stacked is disposed on the second substrate 110, for example, on the second horizontal conductive layer 114 of the second substrate 110.

In an embodiment, the gate stacking structure 120 includes gate stacking structures 120a and 120b that are sequentially stacked on the second substrate 110. The number of the stacked gate electrodes 130 can be increased so that the number of the memory cells can be stably increased. For example, the gate stacking structure 120 includes the first and second gate stacking structures 120a and 120b to increase data storage capacity and simplify the structure. However, embodiments are not necessarily limited thereto, and in some embodiments, the gate stacking structure 120 is configured as one gate stacking structure, or includes at least three gate stacking structures.

In the gate stacking structure 120, the gate electrodes 130 include a lower gate electrode 130L, a memory cell gate electrode 130M, and an upper gate electrode 130U that are sequentially disposed on the second substrate 110. The lower gate electrode 130L is a gate electrode of a ground selecting transistor, the memory cell gate electrode 130M configures a memory cell, and the upper gate electrode 130U is a gate electrode of a string selecting transistor. The number of the memory cell gate electrodes 130M is determined according to the data storage capacity of the semiconductor device 10. Depending on embodiments, one or more of the lower gate electrode 130L and the upper gate electrode 130U are provided, and they may have the same or different structures as/from the memory cell gate electrode 130M. Some of the gate electrodes 130, such as the memory cell gate electrode 130M disposed near the lower gate electrode 130L and the upper gate electrode 130U, may be dummy gate electrodes.

Referring now to FIGS. 3 and 4 in addition to FIGS. 1 and 2, the cell insulation layer 132 includes interlayer insulating layers 132m disposed on lower portions of the gate electrodes 130, or between two neighboring gate electrodes 130 in the first and second gate stacking structures 120a and 120b, and upper insulation layers 132a and 132b disposed on upper portions of the first and second gate stacking structures 120a and 120b, respectively. For example, the upper insulation layers 132a and 132b include a first upper insulation layer 132a disposed on an upper portion of the first gate stacking structure 120a, and a second upper insulation layer 132b disposed on an upper portion of the second gate stacking structure 120b. For example, the first upper insulation layer 132a is an intermediate insulation layer disposed between the first gate stacking structure 120a and the second gate stacking structure 120b, and the second upper insulation layer 132b is an uppermost insulation layer disposed on an uppermost portion of the gate stacking structure 120. The second upper insulation layer 132b configures a portion or all of a cell region insulation layer disposed on an upper portion of the cell region 100. In an embodiment, thicknesses of the cell insulation layers 132 are not identical with each other. For example, the thicknesses of the upper insulation layers 132a and 132b are greater than the thicknesses of the interlayer insulating layers 132m. However, embodiments are not necessarily limited thereto, and forms and structures of the cell insulation layer 132 can be modified in other embodiments.

For simplicity of illustration, the drawing shows that the cell insulation layer 132 has a boundary between the first gate stacking structure 120a and the second gate stacking structure 120b in the contact region 104. However, embodiments are not necessarily limited thereto. In other embodiments, the insulation layers in the contact region 104 have other types of stacking structures.

The gate electrodes 130 include one or more of various conductive materials. For example, the gate electrodes 130 include metallic materials such as one or more of tungsten (W), copper (Cu), or aluminum (Al), etc. For example, the gate electrodes 130 include at least one of polysilicon, a metal nitride, such as titanium nitride (TiN) or tantalum nitride (TaN), etc., or combinations thereof. In addition, an insulation layer made of an insulating material is disposed on the outside of the gate electrodes 130, or a portion of a dielectric layer 150 is disposed thereon. The cell insulation layer 132 includes at least one of various insulating materials. For example, the cell insulation layer 132 includes at least one of a silicon oxide, a silicon nitride, a silicon oxynitride, a low dielectric material that has a lower dielectric constant than silicon oxide, or combinations thereof.

In an embodiment, the channel structure CH may extend in a direction, such as the third direction (or the Z direction), that passes through the gate stacking structure 120 and intersects the second substrate 110.

Referring to FIG. 3 to FIG. 5, in an embodiment, the channel structure CH of the semiconductor device includes a channel layer 140, and a dielectric layer 150 disposed on the channel layer 140 between the gate electrodes 130 and interlayer insulating layers 132 and the channel layer 140. The channel structure CH further includes a core insulation layer 142 disposed inside the channel layer 140, and a channel pad 144 disposed on the channel layer 140 and/or the dielectric layer 150.

Each channel structure CH forms one memory cell string, and the channel structures CH are spaced apart from each other, forming rows and columns in a plan view. For example, the channel structures CH are arranged in various patterns, such as a lattice pattern or an alternate pattern in a plan view.

In an embodiment, the channel structure CH has a pillar shape. For example, when the channel structure CH is seen in a cross-sectional view, it has a lateral side that is inclined so that the width becomes narrower as it approaches the second substrate 110, as shown in FIG. 3, depending on aspect ratios. However, embodiments are not necessarily limited thereto, and in other embodiments, the arrangement, structure, and shape of the channel structure CH can vary.

The channel structure CH penetrates the first and second horizontal conductive layers 112 and 114. The channel structure CH is electrically connected with the first and second horizontal conductive layers 112 and 114.

The core insulation layer 142 is provided in a central region of the channel structure CH, and the channel layer 140 surrounds a sidewall of the core insulation layer 142. For example, the channel layer 140 surrounds the core insulation layer 142. For example, the core insulation layer 142 has a pillar shape, such as a cylindrical shape or a polygonal pillar shape, and the channel layer 140 has a planar shape such as an annular shape in a planar cross section. However, embodiments are not necessarily limited thereto, and in some embodiments, no core insulation layer 142 is provided and the channel layer 140 has a pillar shape. such as a cylindrical shape or a polygonal pillar shape.

The channel layer 140 penetrates the first and second horizontal conductive layers 112 and 114. The channel layer 140 is electrically connected to the first and second horizontal conductive layers 112 and 114. For example, a portion of a lateral side of the channel layer 140 directly contacts a lateral side of the first horizontal conductive layer 112 and is electrically connected to the lateral side thereof.

The channel layer 140 includes a semiconductor material, such as polysilicon. The core insulation layer 142 includes at least one of various insulating materials. For example, the core insulation layer 142 includes at least one of silicon oxide, silicon nitride, silicon oxynitride, or combinations thereof. However, the materials of the channel layer 140 and the core insulation layer 142 are not necessarily limited thereto.

The dielectric layer 150 includes a channel insulation layer 152 and a ferroelectric layer 154 that are sequentially stacked on an exterior side of the channel layer 140.

The channel insulation layer 152 surrounds the channel layer 140. For example, the channel insulation layer 152 extends in the third direction (Z direction) and surrounds a lateral side of the channel layer 140. The channel insulation layer 152 has a planar shape such as an annular shape in a planar cross-section.

The channel insulation layer 152 includes an insulating material. For example, the channel insulation layer 152 include at least one of silicon oxide, silicon nitride, or silicon oxynitride. For example, the channel insulation layer 152 is a stack of a silicon oxide layer and a silicon nitride layer.

The ferroelectric layer 154 surrounds the channel insulation layer 152. The ferroelectric layer 154 extends along a sidewall of the channel insulation layer 152 and has a conformal shape. The ferroelectric layer 154 covers an internal sidewall and a bottom side of the channel insulation layer 152.

In addition, the ferroelectric layer 154 is disposed between the gate dielectric pattern 300 and the channel insulation layer 152 and between the interlayer insulating layers 132m and the channel insulation layer 152. For example, the ferroelectric layer 154 is disposed between the gate electrodes 130 and the channel insulation layer 152. For example, at least a portion of the ferroelectric layer 154 is surrounded by the gate dielectric pattern 300. This will be described below when the gate dielectric pattern 300 is described.

In an embodiment, the ferroelectric layer 154 overlaps the gate dielectric pattern 300 in a radial direction of the channel structure CH. For example, one portion of the ferroelectric layer 154 overlaps the gate dielectric pattern 300 in the radial direction of the channel structure CH, and another portion of the ferroelectric layer 154 overlaps the interlayer insulating layers 132m in the radial direction of the channel structure CH. The ferroelectric layer 154 also directly contacts the gate dielectric pattern 300. For example, an exterior side of the ferroelectric layer 154 directly contacts the gate dielectric pattern 300 that is spaced apart and arranged in the third direction (Z direction).

The ferroelectric layer 154 includes a ferroelectric material. For example, the ferroelectric layer 154 includes a ferroelectric Hf compound. For example, the ferroelectric layer 154 includes at least one of HfO₂, HfZnO, HfSiO, HfSiON, HfTaO, HfTiO, HfZrO, or combinations thereof. The ferroelectric layer 154 may, for example, include a ferroelectric material in a perovskite structure such as PZT(PbZrxTi1−xO₃), BaTiO₃, or PbTiO₃. The ferroelectric layer 154 includes at least one dopant selected from carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), zirconium (Zr), gadolinium (Gd), or lanthanum (La). The ferroelectric layer 154 may be crystalline. For example, the ferroelectric layer 154 has an orthorhombic crystal structure.

In an embodiment, the ferroelectric layer 154 can have various states of polarization, depending on a voltage applied between the gate electrodes 130 and the channel layer 140. For example, the ferroelectric layer 154 has a residual polarization due to the voltage applied between the gate electrodes 130 and the channel structure CH. For example, a magnitude of the residual polarization generated in the ferroelectric layer 154 is determined by the magnitude of the voltage applied between the gate electrodes 130 and the channel layer 140, and a polarization-voltage (PV) hysteresis due to a process through which the residual polarization is generated in the ferroelectric layer 154. The generated residual polarization is stored in the ferroelectric layer 154, and signal information can be stored in a nonvolatile way by the stored residual polarization. For example, the ferroelectric layer 154 functions as a nonvolatile memory layer.

The gate dielectric pattern 300 is disposed on a lateral side of the channel structure CH.

For example, the gate dielectric pattern 300 is disposed on an exterior side of the ferroelectric layer 154. The gate dielectric pattern 300 is disposed between the gate electrodes 130 and the channel structure CH. The gate dielectric pattern 300 directly contacts a lateral side of the ferroelectric layer 154.

In an embodiment, the gate dielectric pattern 300 surrounds at least a portion of the channel structure CH. For example, the gate dielectric pattern 300 extends in a circumferential direction of the channel structure CH, and surrounds a portion of an exterior side of the ferroelectric layer 154. For example, the gate dielectric pattern 300 has an annular shape in a plan view. For example, the gate dielectric pattern 300 covers the lateral side of the ferroelectric layer 154 in the circumferential direction of the channel structure CH.

Further, the gate dielectric patterns 300 are spaced apart from each other with predetermined intervals therebetween in the third direction (the Z direction). For example, the gate dielectric patterns 300 are spaced apart from each other in the third direction (the Z direction). The gate dielectric patterns 300 spaced apart in the third direction (Z direction) surround the channel structure CH.

Hence, the gate dielectric pattern 300 is disposed between the gate electrodes 130 and the ferroelectric layer 154, but not disposed between the interlayer insulating layers 132m and the ferroelectric layer 154. For example, the gate dielectric pattern 300 overlaps the gate electrodes 130 in the radial direction of the channel structure CH, but does not overlap the interlayer insulating layers 132m in the radial direction of the channel structure CH.

The gate dielectric pattern 300 includes a charge inflow pattern 310 and an insulation pattern 320.

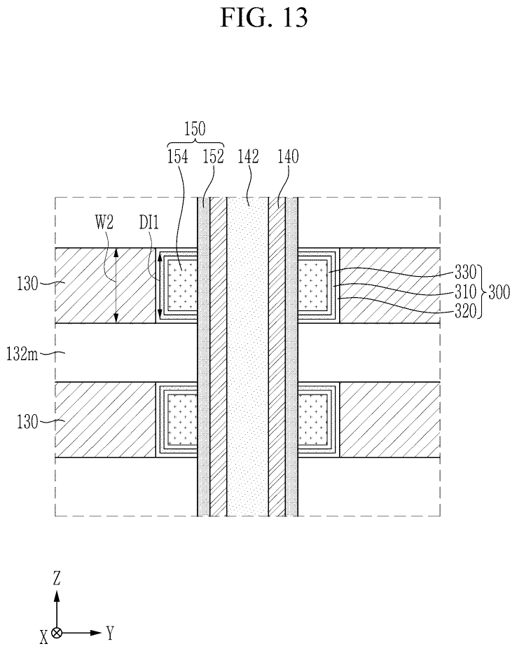

The charge inflow pattern 310 is disposed on the lateral side of the channel structure CH. For example, the charge inflow pattern 310 is disposed on the exterior side of the ferroelectric layer 154. The charge inflow pattern 310 is disposed between the gate electrodes 130 and the channel structure CH. The charge inflow pattern 310 directly contacts the lateral side of the ferroelectric layer 154. However, embodiments are not necessarily limited thereto, and a tunneling layer 330 of FIG. 13 may be further disposed between the charge inflow pattern 310 and the ferroelectric layer 154. This will be described below with reference to FIG. 13.

In an embodiment, the charge inflow pattern 310 surrounds at least a portion of the channel structure CH. For example, the charge inflow pattern 310 extends in the circumferential direction of the channel structure CH, and surrounds at least a portion of the exterior side of the ferroelectric layer 154. For example, the charge inflow pattern 310 has an annular shape in a plan view. For example, the charge inflow pattern 310 covers the lateral side of the ferroelectric layer 154 in the circumferential direction of the channel structure CH.

The charge inflow patterns 310 are spaced apart from each other with predetermined intervals therebetween in the third direction (Z direction). For example, the charge inflow patterns 310 are spaced apart from each other in the third direction (Z direction). The charge inflow patterns 310 spaced apart in the third direction (Z direction) surround the channel structure CH.

Hence, the charge inflow pattern 310 are disposed between the gate electrodes 130 and the ferroelectric layer 154, but not between the interlayer insulating layers 132m and the ferroelectric layer 154. For example, the charge inflow pattern 310 overlaps the gate electrodes 130 in the radial direction of the channel structure CH, but does not overlap the interlayer insulating layers 132m in the radial direction of the channel structure CH. A first width W1 of the charge inflow pattern 310 in the third direction (the Z direction) is less than a second width W2 of the gate electrodes 130 in the third direction (the Z direction). This is because the insulation pattern 320 covers upper sides and lower sides of the charge inflow patterns 310.

In an embodiment, the charge inflow pattern 310 have a first thickness T1 in the radial direction of the channel structure CH. For example, the first thickness T1 of the charge inflow pattern 310 in the radial direction in the channel structure CH is from 0.5 nm to 20 nm. In this range, the charge inflow pattern 310 functions as a charge inflow layer that changes the polarization of the ferroelectric layer 154. The first thickness T1 of the charge inflow pattern 310 in the radial direction of the channel structure CH is substantially equivalent to the thickness of the charge inflow pattern 310 in the second direction (Y direction) in a cross-section in the second direction (Y direction) and the third direction (Z direction), as shown in FIG. 5. The charge inflow pattern 310 may include silicon nitride (SiN), but is not necessarily limited thereto.

Residual polarization can be generated in the ferroelectric layer 154 of the semiconductor device 10 by a voltage applied between the gate electrodes 130 and the channel structure CH. For example, an electric field is generated in the charge inflow pattern 310 by the voltage applied to the gate electrodes 130. Hence, charge can easily flow into the charge inflow pattern 310, and the residual polarization is easily generated in the ferroelectric layer 154. For example, when the voltage applied to the gate electrodes 130 is reduced, the electric field is generated in the charge inflow pattern 310 and the residual polarization is easily generated in the ferroelectric layer 154. For example, an operating voltage that generates the residual polarization in the ferroelectric layer 154 is decreased.

In addition, the charge inflow pattern 310 are spaced apart in the third direction (Z direction). For example, the charge inflow pattern 310 is disposed between the gate electrodes 130 and the ferroelectric layer 154 but not between the interlayer insulating layers 132m and the ferroelectric layer 154. Hence, when the voltage is applied to the gate electrode 130, the electric field is generated in the charge inflow pattern 310 disposed on the side of the gate electrode 130 to which the voltage is applied. Therefore, no interference is generated between the charge inflow patterns 310 spaced apart in the third direction (Z direction).

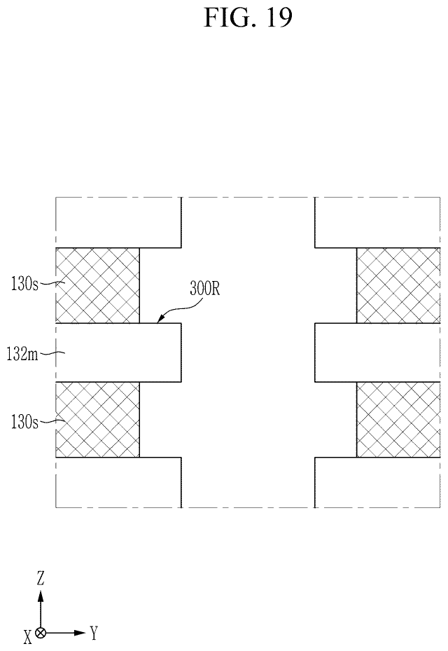

The insulation pattern 320 surrounds at least a portion of the charge inflow pattern 310. For example, the insulation pattern 320 surrounds an upper side 310U, a lower side 310B, and an exterior side 310S of the charge inflow pattern 310. For example, the insulation pattern 320 is disposed on the upper side 310U of the charge inflow pattern 310, the lower side 310B of the charge inflow pattern 310, and the exterior side 310S of the charge inflow pattern 310. The insulation pattern 320 is conformally disposed on an internal sidewall of the gate dielectric recess 300R of FIG. 19. The insulation pattern 320 contacts the upper side 310U of the charge inflow pattern 310, the lower side 310B of the charge inflow pattern 310, and the exterior side 310S of the charge inflow pattern 310.

In an embodiment, the insulation pattern 320 extends in the circumferential direction of the channel structure CH. For example, the insulation pattern 320 extends in the circumferential direction of the channel structure CH, and covers the upper side 310U, the lower side 310B, and the exterior side 310S of the charge inflow pattern 310. For example, a portion of the insulation pattern 320 disposed on the upper side 310U and the lower side 310B of the charge inflow pattern 310 and a portion of the insulation pattern 320 disposed on the exterior side 310S of the charge inflow pattern 310 extend in the circumferential direction of the channel structure CH.

Hence, the insulation pattern 320 is disposed between the exterior side 310S of the charge inflow pattern 310 and the gate electrodes 130. Further, the insulation pattern 320 is disposed between the upper side 310U of the charge inflow pattern 310 and the interlayer insulating layers 132m and between the lower side 310B of the charge inflow pattern 310 and the interlayer insulating layers 132m. The insulation pattern 320 directly contacts the charge inflow pattern 310, the gate electrodes 130, and the interlayer insulating layers 132m.

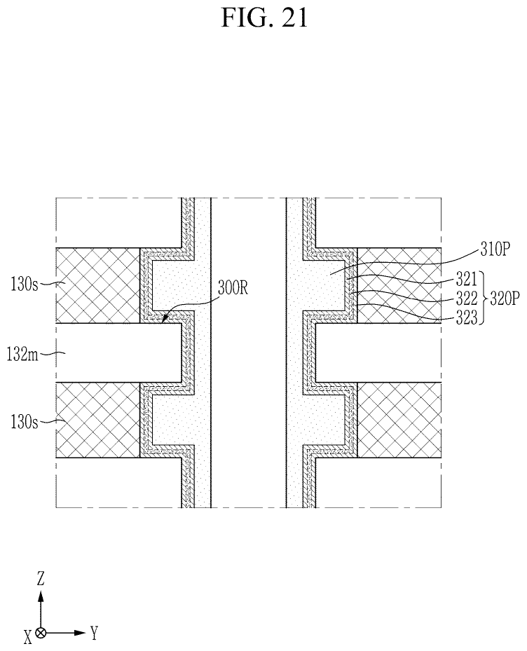

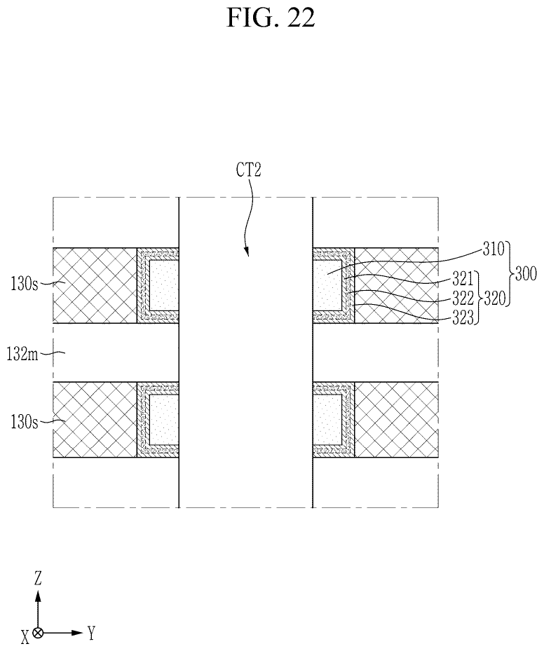

In an embodiment, the insulation pattern 320 directly contacts the ferroelectric layer 154. For example, ends of the insulation pattern 320 located on the upper side 310U and the lower side 310B of the charge inflow pattern 310 directly contact the ferroelectric layer 154. For example, the ends of the insulation pattern 320 located on the upper side 310U and the lower side 310B of the charge inflow pattern 310 are disposed on a lateral side of the charge inflow pattern 310. This is caused by a process of forming the second channel hole CT2 of FIG. 22 by simultaneously etching a preliminary insulation pattern 320P of FIG. 21 and a preliminary charge inflow pattern 310P of FIG. 21 after forming the preliminary insulation pattern 320P of FIG. 21 and the preliminary charge inflow pattern 310P of FIG. 21 in the gate dielectric recess 300R of FIG. 19, and described below.

In an embodiment, a second thickness T2 of the insulation pattern 320 in the radial direction of the channel structure CH is less than the first thickness T1 of the charge inflow pattern 310 in the radial direction of the channel structure CH. The second thickness T2 of the insulation pattern 320 in the radial direction of the channel structure CH represents the thickness of a portion of the insulation pattern 320 disposed between the gate electrodes 130 and the charge inflow pattern 310 in the radial direction of the channel structure CH. In addition, the thickness of the portion of the insulation pattern 320 disposed between the gate electrodes 130 and the charge inflow pattern 310 in the radial direction of the channel structure CH is substantially equal to the thickness of the portion of the insulation pattern 320 disposed between the charge inflow pattern 310 and the interlayer insulating layers 132m in the third direction (Z direction), but is not necessarily limited thereto.

In an embodiment, the second thickness T2 of the insulation pattern 320 in the radial direction of the channel structure CH is substantially equal to the thickness of the portion of the insulation pattern 320 disposed between the gate electrodes 130 and the charge inflow pattern 310 in the second direction (Y direction) a the cross-section in the second direction (Y direction) and the third direction (Z direction), as shown in FIG. 5. For example, the thickness of the portion of the insulation pattern 320 disposed between the gate electrodes 130 and the charge inflow pattern 310 in the second direction (Y direction) is less than the thickness of the charge inflow pattern 310 in the second direction (Y direction).

The insulation pattern 320 of the gate dielectric pattern 300 includes a first portion 321, a second portion 322, and a third portion 323 that are sequentially disposed from the exterior side of the ferroelectric layer 154.

The first portion 321 surrounds at least a portion of the charge inflow pattern 310. For example, the first portion 321 surrounds the upper side 310U, the lower side 310B, and the exterior side 310S of the charge inflow pattern 310. For example, the first portion 321 is disposed on the upper side 310U of the charge inflow pattern 310, the lower side 310B of the charge inflow pattern 310, and the exterior side 310S of the charge inflow pattern 310. The first portion 321 is disposed between the charge inflow pattern 310 and the second portion 322. The first portion 321 directly contacts the charge inflow pattern 310 and the second portion 322.

The first portion 321 extends in the circumferential direction of the channel structure CH. For example, the first portion 321 covers the upper side 310U, the lower side 3101B, and the exterior side 310S of the charge inflow pattern 310. For example, a portion of the first portion 321 disposed on the upper side 310U and the lower side 310B of the charge inflow pattern 310 and a portion of the first portion 321 disposed on the exterior side 310S of the charge inflow pattern 310 extend in the circumferential direction of the channel structure CH.

The second portion 322 surrounds the first portion 321. For example, the second portion 322 surrounds an upper side, a lower side, and an exterior side of the first portion 321. For example, the second portion 322 is disposed on the upper side, the lower side, and the exterior side of the first portion 321. The second portion 322 is disposed between the first portion 321 and the third portion 323. The second portion 322 directly contacts the first portion 321 and the third portion 323.

The third portion 323 surrounds the second portion 322. For example, the third portion 323 surrounds the upper side, the lower side, and the exterior side of the second portion 322. For example, the third portion 323 is disposed on the upper side, the lower side, and the exterior side of the second portion 322. The third portion 323 may be disposed between the second portion 322 and the gate electrodes 130 and between the second portion 322 and the interlayer insulating layers 132m. The third portion 323 directly contacts the second portion 322, the gate electrodes 130, and the interlayer insulating layers 132m.

In an embodiment, the first to third portions 323 include one or more of various types of insulating materials. For example, the first to third portions 323 include silicon oxide (SiO₂). However, without being necessarily limited thereto, the first to third portions 323 include at least one of silicon nitride (SiN), silicon oxynitride (SiON), silicon oxycarbide (SiOC), silicon oxycarbonitride (SiOCN), or silicon carbonitride (SiCN).

In an embodiment, the first to third portions 323 include a dopant. For example, the dopant includes nitrogen (N), but is not necessarily limited thereto. For example, the insulation pattern 320 includes a portion that has a different dopant concentration. For example, at least one of the first to third portions 323 has a different dopant concentration.

For example, referring to FIG. 6 and FIG. 7, the dopant concentration of the insulation pattern 320 includes a portion that reduces with increasing distance from the charge inflow pattern 310.

For example, as shown in FIG. 6, the dopant concentration of the insulation pattern 320 increases and then decreases with increasing distance from the charge inflow pattern 310. The dopant concentration is greatest in the second portion 322. For example, the dopant concentration of the second portion 322 is greater than the dopant concentration of the first portion 321. The dopant concentration of the second portion 322 is greater than the dopant concentration of the third portion 323.

In another embodiment, as shown in FIG. 7, the dopant concentration of the insulation pattern 320 monotonically decreases with increasing distance from the charge inflow pattern 310. For example, the dopant concentration of the first portion 321 is greater than the dopant concentration of the second portion 322. The dopant concentration of the second portion 322 is greater than the dopant concentration of the third portion 323. However, without being necessarily limited thereto, the dopant concentration of the insulation pattern 320 can vary in many ways within a range that includes a portion where it decreases with increasing distance from the charge inflow pattern 310.

Since the insulation pattern 320 of the gate dielectric pattern 300 surrounds at least a portion of the charge inflow pattern 310, when a voltage is applied to the gate electrodes 130, the electric field is generated in the charge inflow pattern 310 disposed on the side of the gate electrode 130 to which the voltage is applied. For example, interference between the charge inflow patterns 310 spaced apart in the third direction (Z direction) can be prevented.

The insulation pattern 320 of the gate dielectric pattern 300 includes the first to third portions 321 to 323 to which predetermined dopants are doped, and the dopant concentration of at least one of the first to third portions 321 to 323 is different. Hence, when a voltage is applied to the gate electrodes 130, the electric field is generated in the charge inflow pattern 310 according to the dopant concentration. Therefore, charges easily flow to the charge inflow pattern 310, and hence, a residual polarization is easily generated in the ferroelectric layer 154.

Referring to FIG. 1 and FIG. 2, in an embodiment, a channel pad 144 is disposed on the channel layer 140 and/or the dielectric layer 150. The channel pad 144 covers the upper side of the core insulation layer 142 and is electrically connected to the channel layer 140. The channel pad 144 is shown as covering the upper side of the dielectric layer 150, but is not necessarily limited thereto. For example, in some embodiment, the channel pad 144 does not cover the upper side of the dielectric layer 150. For example, a lateral side of the channel pad 144 is surrounded by the dielectric layer 150. The lateral side of the channel pad 144 directly contacts the channel insulation layer 152. The channel pad 144 includes a conductive material, such as impurity-doped polysilicon. However, the material of the channel pad 144 is not necessarily limited thereto, and can be varied in many ways.

When the gate stacking structure 120 includes stacked gate stacking structures 120a and 120b, the channel structure CH includes channel structures CH1 and CH2 that penetrates the gate stacking structures 120a and 120b. For example, when the gate stacking structures 120 include the first gate stacking structure 120a and the second gate stacking structure 120b, the channel structures CH include a first channel structure CH1 that penetrates the first gate stacking structure 120a, and a second channel structure CH2 that penetrates the second gate stacking structure 120b.

The first channel structure CH1 is connected to the second channel structure CH2. The first channel structure CH1 and the second channel structure CH2 each have a lateral side that is inclined so that the width becomes narrower when approaching the second substrate 110 according to an aspect ratio in a cross-sectional view. As shown in FIG. 3, in an embodiment, a bent portion is provided where the first channel structure CH1 is connected to the second channel structure CH2 due to a difference in width. For example, in an embodiment shown in FIG. 4, the first channel structure CH1 and the second channel structure CH2 have continuously connected inclined lateral sides with no bent portion. However, the shapes of the first channel structure CH1 and the second channel structure CH2 are not necessarily limited thereto, and can be modified in many ways.

FIG. 1 and FIG. 2 show that the dielectric layer 150, the channel layer 140, and the core insulation layer 142 of the first channel structure CH1 and the second channel structure CH2 extend with each other to form an integral structure. When forming a first penetration portion for the first channel structure CH1 and a second penetration portion for the second channel structure CH2, the dielectric layer 150, the channel layer 140, and the core insulation layer 142 are formed over the first and second penetration portions to form the above-described structure. However, embodiments are not necessarily limited thereto. For example, in other embodiments, the dielectric layers 150, the channel layers 140, and the core insulation layers 142 of first channel structure CH1 and the second channel structure CH2 are formed separately from each other and are electrically connected to each other. For example, the dielectric layer 150, the channel layer 140, and the core insulation layer 142 are formed in the first penetration portion when the first penetration portion for the first channel structure CH1 is formed, and the dielectric layer 150, the channel layer 140, and the core insulation layer 142 are formed in the second penetration portion when the second penetration portion for the second channel structure CH2 is formed. Various other changes are possible.

In an embodiment, the channel pad 144 is disposed on the channel structure CH, such as the second channel structure CH2, disposed in the gate stacking structure 120, such as the second gate stacking structure 120b, disposed on an upper portion of the gate stacking structures 120. In an embodiment, the channel pad 144 is disposed on the first channel structure CH1 and the second channel structure CH2. For example, the channel pad 144 of the first channel structure CH1 is connected to the channel layer 140 of the second channel structure CH2.

In an embodiment, the gate stacking structure 120 extends in a direction, such as the third direction (Z direction), that crosses the second substrate 110 and is partitioned into multiple portions in a plan view by a separation structure 146 that penetrates the gate stacking structure 120

For example, the separation structure 146 penetrates the gate electrodes 130 and the cell insulation layer 132 and extends to an upper side of the second substrate 110. In a plan view, a plurality of the separation structures 146 are provided so that the separation structures 146 extend in the first direction (X direction) and are spaced apart from each other at predetermined intervals in the second direction (Y direction) that crosses the first direction (X direction). Hence, in a plan view, the gate stacking structures 120 extend in the first direction (X direction) and are spaced apart from each other at predetermined intervals in the second direction (Y direction). A gate stacking structure 120 partitioned by the separation structure 146 constitutes one memory cell block. However, embodiments are not necessarily limited thereto, and a range of the memory cell block is not necessarily limited thereto.

The separation structure 146 has an inclined lateral side that decreases in width toward the second substrate 110 when seen in a cross-sectional view because of a high aspect ratio. However, embodiments are not necessarily limited thereto, and in other embodiments, the lateral side of the separation structure 146 is perpendicular to the second substrate 110. FIG. 2 illustrates that the separation structure 146 has a continuous inclined lateral side in the first gate stacking structure 120a and the second gate stacking structure 120b and does not have a bent part in a cross-sectional view. However, embodiments are not necessarily limited thereto, and in other embodiments, the separation structure 146 has a bent portion at a boundary between the first gate stacking structure 120a and the second gate stacking structure 120b.

The separation structure 146 includes one or more of various types of insulating materials. For example, the separation structure 146 includes an insulating material such as at least one of silicon oxide, silicon nitride, or silicon oxynitride. However, embodiments are not necessarily limited thereto, and the structure, shape, and material of the separation structure 146 can change in other embodiments.

The semiconductor device further includes an upper separation pattern 148.

The upper separation pattern 148 is disposed on an upper portion of the gate stacking structure 120. In a plan view, a plurality of the upper separation patterns 148 are provided so that they can extend in the first direction (X direction) and be spaced apart from each other at predetermined intervals in the second direction (Y direction).

The upper separation pattern 148 penetrates through one or a plurality of gate electrodes 130 that include the upper gate electrodes 130U disposed between the separation structure 146. For example, the upper separation pattern 148 separates two gate electrodes 130 in the second direction (Y direction). However, the number of the gate electrodes 130 separated by the upper separation pattern 148 is not necessarily limited thereto, and can vary in many ways.

The upper separation pattern 148 includes an insulating material. For example, the upper separation pattern 148 includes at least one of silicon oxide (SiO₂), silicon nitride (SiN), or silicon oxynitride (SiON). However, embodiments are not necessarily limited thereto, and the structure, shape, and material of the upper separation pattern 148 can vary in many ways.

To connect the gate stacking structure 120 and the channel structure CH in the cell array region 102 to the circuit region 200 or an external circuit, the contact region 104 and the second wire portion 180 are provided.

The second wire portion 180 includes components that electrically connect the gate electrodes 130, the channel structure CH, and/or the second substrate 110 to the circuit region 200 or the external circuit. For example, the second wire portion 180 includes a bit line 182, a gate contact portion 184, a source contact portion 186, a penetration plug 188, contact vias 180a respectively connected to them, and a connecting wire 190 that connects them.

The bit line 182 is disposed on the cell insulation layer 132 of the gate stacking structure 120 in the cell array region 102. The bit line 182 extends in the second direction (Y direction). The bit line 182 is electrically connected to the channel structure CH by, for example, the channel pad 144 through the contact via 180a, or a bit line contact via.

The contact region 104 is arranged near the cell array region 102. A portion of the second wire portion 180 is disposed in the contact region 104. The contact region 104 includes a gate stacking structure 120 disposed on the second substrate 110, and a gate contact portion 184 that connects the gate electrodes 130 of the cell array region 102 to the circuit region 200 or the external circuit.

For example, the gate electrodes 130 extend in the first direction (X direction) in the contact region 104, and extending lengths the first direction (X direction) of the gate electrodes 130 in the contact region 104 sequentially decrease with increasing distance from the second substrate 110. For example, the gate electrodes 130 form a stair shape in the contact region 104. For example, the gate electrodes 130 may have a stair shape in one direction or a plurality of directions. In the contact region 104, the gate contact portions 184 penetrate the cell insulation layer 132 and are electrically connected to the gate electrodes 130 that extend into the contact region 104.

In the contact region 104, the source contact portion 186 penetrates the cell insulation layer 132 and is electrically connected to the second substrate 110. For example, the source contact portion 186 penetrates the second horizontal conductive layer 114 and the horizontal insulation layer 116 and is electrically connected to the second substrate 110.

The penetration plug 188 penetrates the gate stacking structure 120 or is disposed outside the gate stacking structure 120 and is electrically connected to the first wire portion 230 of the circuit region 200. However, embodiments are not necessarily limited thereto.

A connecting wire 190 is disposed in the cell array region 102 and/or the contact region 104. The bit line 182, the gate contact portion 184, the source contact portion 186 and/or the penetration plug 188 are electrically connected to the connecting wire 190. For example, the gate contact portion 184, the source contact portion 186, and/or the penetration plug 188 are connected to the connecting wire 190 through the contact via 180a.

FIG. 1 shows that the connecting wire 190 is a single layer disposed on the same plane as the bit line 182, and a second insulation layer 192 is disposed on a portion that is not the second wire portion 180. However, this is shown for convenience. Therefore, the connecting wire 190 includes a plurality of wire layers that electrical connect with the bit line 182, the gate contact portion 184, the source contact portion 186 and/or the penetration plug 188, and may further include contact vias.

As described above, the bit line 182, the gate electrodes 130, and/or the second substrate 110 connected to the channel structure CH are electrically connected to the circuit element 220 of the circuit region 200 by the second wire portion 180 and the first wire portion 230.

Referring to FIG. 1, in an embodiment, in a cross-sectional view, the gate contact portion 184, the source contact portion 186 and/or the penetration plug 188 have an inclined lateral side so that their widths become narrower as they approach the second substrate 110, according to the aspect ratio, and a bent portion is provided at the boundary between the first gate stacking structure 120a and the second gate stacking structure 120b. However, embodiments are not necessarily limited to this. For example, in other embodiments, the gate contact portion 184, the source contact portion 186 and/or the penetration plug 188 do not have a bent portion at the boundary between the first gate stacking structure 120a and the second gate stacking structure 120b. Various other changes are possible.

Residual polarization can be generated in the ferroelectric layer 154 of the semiconductor device 10 by a voltage applied between the gate electrodes 130 and the channel structure CH. For example, an electric field is generated in the charge inflow pattern 310 according to a voltage applied to the gate electrodes 130. Hence, charges can easily flow into the charge inflow pattern 310, and a residual polarization is generated in the ferroelectric layer 154. For example, when the voltage applied to the gate electrodes 130 decreases, the electric field is generated in the charge inflow pattern 310 and the residual polarization is easily generated in the ferroelectric layer 154.

The insulation pattern 320 of the gate dielectric pattern 300 includes the first to third portions 321 to 323 to which predetermined dopants are doped, and in which the dopant concentration of at least one of the first to third portions 321 to 323 is different. Hence, when a voltage is applied to the gate electrodes 130, the electric field is easily generated in the charge inflow pattern 310 according to the dopant concentration. Therefore, charge can easily flow into the charge inflow pattern 310, and hence, residual polarization is easily generated in the ferroelectric layer 154. For example, the operating voltage for generating the residual polarization in the ferroelectric layer 154 is reduced, and reliability of the semiconductor device 10 is increased.

In addition, the charge inflow patterns 310 are spaced apart in the third direction (Z direction). For example, the charge inflow patterns 310 are disposed between the gate electrodes 130 and the ferroelectric layer 154 but not between the interlayer insulating layers 132m and the ferroelectric layer 154. Further, the insulation pattern 320 of the gate dielectric pattern 300 surrounds at least a portion of the charge inflow pattern 310. Hence, when a voltage is applied to the gate electrode 130, the electric field is generated in the charge inflow pattern 310 disposed on a side of the gate electrode 130 to which the voltage is applied. Therefore, no interference is generated between the charge inflow patterns 310 spaced apart in the third direction (Z direction), and reliability of the semiconductor device 10 is increased.

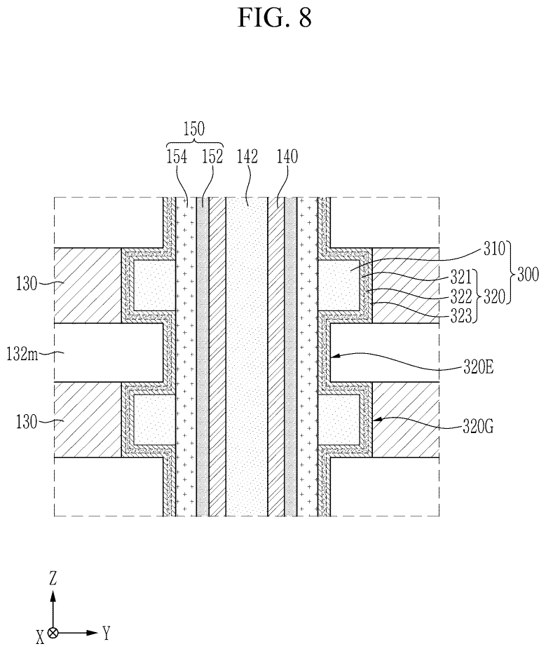

A semiconductor device according to several embodiments will now be described with reference to FIG. 8 to FIG. 14. Parts that are identical or extremely similar to those already described will not be described, and parts that are different will be described in detail.

FIG. 8 is a cross-sectional view of a region S1 of a semiconductor device shown in FIG. 2 according to several embodiments.

A semiconductor device according to an embodiment shown in FIG. 8 mostly corresponds to a semiconductor device according to an embodiment shown in FIG. 1 to FIG. 7 so that repeated descriptions thereof may be omitted and differences thereof will be mainly described. In addition, the same or similar reference numerals may be used for constituent elements that are identical or similar to those of a previous embodiment. A present embodiment differs from a previous embodiment in that the shape of the insulation pattern 320 differs from a previous embodiment, which will be described below.

Referring to FIG. 1 and FIG. 8, the cell region 100 of the semiconductor device 10 includes a second substrate 110, a gate stacking structure 120 disposed on the second substrate 110, a channel structure CH that penetrates the gate stacking structure 120 and includes a channel layer 140 and a ferroelectric layer 154, and a gate dielectric pattern 300 disposed on a lateral side of the ferroelectric layer 154.

The gate dielectric pattern 300 includes a charge inflow pattern 310 and an insulation pattern 320.

In a previous embodiment, a plurality of the charge inflow patterns 310 and the insulation patterns 320 are provided so that they can be spaced apart at predetermined intervals in the third direction (Z direction). For example, the charge inflow patterns 310 are spaced apart in the third direction (Z direction). The insulation patterns 320 are spaced apart in the third direction (Z direction). Hence, the interlayer insulating layers 132m are in direct contact with the ferroelectric layer 154.

Referring to FIG. 8, in an embodiment, the insulation pattern 320 includes a first pattern portion 320G disposed between the ferroelectric layer 154 and the gate electrodes 130 and a second pattern portion 320E disposed between the ferroelectric layer 154 and the interlayer insulating layers 132m.

The first pattern portion 320G of the insulation pattern 320 surrounds the charge inflow pattern 310. For example, the first pattern portion 320G of the insulation pattern 320 covers an upper side, a lower side, and a lateral side of the charge inflow pattern 310. The description of the first pattern portion 320G of the insulation pattern 320 is substantially to the same as the description on the insulation pattern 320 shown in FIG. 1 to FIG. 7, and a repeated description thereof will be omitted.

The second pattern portion 320E of the insulation pattern 320 is disposed between first pattern portions 320G of the insulation pattern 320 that are adjacent in the third direction (Z direction). The second pattern portion 320E of the insulation pattern 320 extends in the third direction (Z direction) and connects adjacent first pattern portion 320G in the third direction (Z direction). The second pattern portion 320E of the insulation pattern 320 overlaps the interlayer insulating layers 132m in the radial direction of the channel structure CH. The second pattern portion 320E of the insulation pattern 320 directly contacts the ferroelectric layer 154. Hence, the ferroelectric layer 154 and the interlayer insulating layers 132m are spaced apart from each other in the radial direction of the channel structure CH. The second pattern portion 320E of the insulation pattern 320 is integrally formed with the first pattern portion 320G of the insulation pattern 320 without a boundary therebetween. The second pattern portion 320E and the first pattern portion 320G include first to third portions 321 to 323 that are substantially the same as those of the insulation pattern 320 of FIG. 5.

In an embodiment, the second pattern portion 320E of the insulation pattern 320 is formed when the portion of the preliminary insulation pattern 320P of FIG. 21 disposed on the lateral side of the interlayer insulating layers 132m is not etched in a process of simultaneously etching the preliminary insulation pattern 320P of FIG. 21 and the preliminary charge inflow pattern 310P of FIG. 21 after forming the preliminary insulation pattern 320P of FIG. 21 and the preliminary charge inflow pattern 310P of FIG. 21 in the gate dielectric recess 300R of FIG. 19.

A lateral side of the second pattern portion 320E of the insulation pattern 320 alternates with a lateral side of the charge inflow pattern 310. For example, a lateral side of the second pattern portion 320E of the insulation pattern 320 that directly contacts the ferroelectric layer 154 alternates in the third direction (Z direction) with a lateral side of the charge inflow pattern 310 that directly contacts the ferroelectric layer 154, but embodiments are not necessarily limited thereto. This is caused by a process of forming the second channel hole CT2 of FIG. 22 by simultaneously etching the preliminary insulation pattern 320P of FIG. 21 and the preliminary charge inflow pattern 310P of FIG. 21 after forming the preliminary insulation pattern 320P of FIG. 21 and the preliminary charge inflow pattern 310P of FIG. 21 in the gate dielectric recess 300R of FIG. 19, and described below.

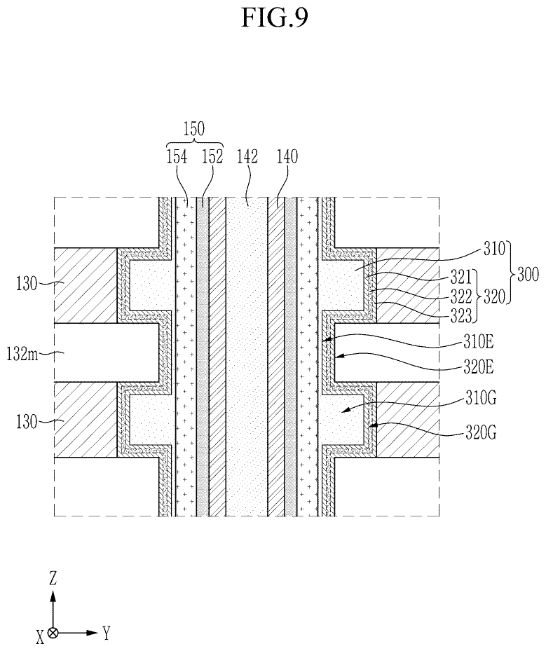

However, the charge inflow patterns 310 are spaced apart at predetermined intervals in the third direction (Z direction). For example, the insulation patterns 320 surround an upper side, a lower side, and a lateral side of the charge inflow patterns 310, and cover a portion of a lateral side of the ferroelectric layer 154. However, without being necessarily limited thereto, the charge inflow patterns 310 are further disposed between the ferroelectric layer 154 and the interlayer insulating layers 132m. This will be described below with reference to FIG. 9.

FIG. 9 is a cross-sectional view of a region S1 of a semiconductor device shown in FIG. 2 according to several embodiments.

A semiconductor device according to an embodiment of FIG. 9 mostly corresponds to a semiconductor device according to an embodiment of FIG. 8 so a repeated description thereof will be omitted and the differences will be mainly described. In addition, the same or similar reference numerals may be used for constituent elements that are identical or similar to those of a previous embodiment. A present embodiment differs from a previous embodiment in that the shape of the charge inflow pattern 310 differs from that of a previous embodiment, which will be described below.

Referring to FIG. 1 and FIG. 9, in an embodiment, the cell region 100 of the semiconductor device 10 includes a second substrate 110, a gate stacking structure 120 disposed on the second substrate 110, a channel structure CH that penetrates the gate stacking structure 120 and includes a channel layer 140 and a ferroelectric layer 154, and a gate dielectric pattern 300 disposed on a lateral side of the ferroelectric layer 154.

The gate dielectric pattern 300 includes a charge inflow pattern 310 and an insulation pattern 320.

In a previous embodiment, a plurality of the charge inflow patterns 310 were provided and spaced apart at predetermined intervals in the third direction (Z direction). The second pattern portion 320E of the insulation pattern 320 directly contacts the ferroelectric layer 154.

Referring to FIG. 9, in an embodiment, the charge inflow pattern 310 includes a first pattern portion 310G disposed between the ferroelectric layer 154 and the gate electrodes 130 and a second pattern portion 310E disposed between the ferroelectric layer 154 and the interlayer insulating layers 132m.

The first pattern portion 310G of the charge inflow pattern 310 is disposed on a lateral side of the channel structure CH. For example, the first pattern portion 310G of the charge inflow pattern 310 is disposed on an exterior side of the ferroelectric layer 154. The first pattern portion 310G of the charge inflow pattern 310 is disposed between the gate electrodes 130 and the channel structure CH. A description of the first pattern portion 310G of the charge inflow pattern 310 is substantially to the same as the description on the charge inflow pattern 310 shown in FIG. 1 to FIG. 7, so a repeated description thereof will be omitted.

The second pattern portion 310E of the charge inflow pattern 310 is disposed between first pattern portions 310G of the charge inflow pattern 310 that are adjacent in the third direction (Z direction). The second pattern portions 310E of the charge inflow pattern 310 extends in the third direction (Z direction) and are connected between adjacent first pattern portions 310G. The second pattern portion 310E of the charge inflow pattern 310 overlaps the interlayer insulating layers 132m in the radial direction of the channel structure CH. The second pattern portion 310E of the charge inflow pattern 310 directly contacts the ferroelectric layer 154. Hence, the ferroelectric layer 154 is spaced apart from the interlayer insulating layers 132m. The second pattern portion 310E of the charge inflow pattern 310 are integrally formed with the first pattern portion 310G of the charge inflow pattern 310 without a boundary therebetween.

In an embodiment, the second pattern portion 310E of the charge inflow pattern 310 is formed when the portion of the preliminary charge inflow pattern 310P of FIG. 21 disposed on the lateral side of the interlayer insulating layers 132m is not etched in a process of simultaneously etching the preliminary insulation pattern 320P of FIG. 21 and the preliminary charge inflow pattern 310P of FIG. 21 after forming the preliminary insulation pattern 320P of FIG. 21 and the preliminary charge inflow pattern 310P of FIG. 21 in the gate dielectric recess 300R of FIG. 19.

For example, the thickness of the first pattern portion 310G of the charge inflow pattern 310 in the radial direction of the channel structure CH is greater than the thickness of the second pattern portion 310E of the charge inflow pattern 310 in the radial direction of the channel structure CH. For example, the thickness of the first pattern portion 310G of the charge inflow pattern 310 in the second direction (Y direction) is greater than the thickness of the second pattern portion 310E of the charge inflow pattern 310 in the second direction (Y direction).

In the semiconductor device 10, since the first pattern portion 320G of the insulation pattern 320 surrounds the first pattern portion 310G of the charge inflow pattern 310, an electric field is gathered in the charge inflow pattern 310 according to the voltage applied to the gate electrodes 130. Hence, charge can easily flow into the charge inflow pattern 310, and a residual polarization is easily generated in the ferroelectric layer 154. For example, when the voltage applied to the gate electrodes 130 is reduced, the electric field is generated in the charge inflow pattern 310 and the residual polarization is easily generated in the ferroelectric layer 154.

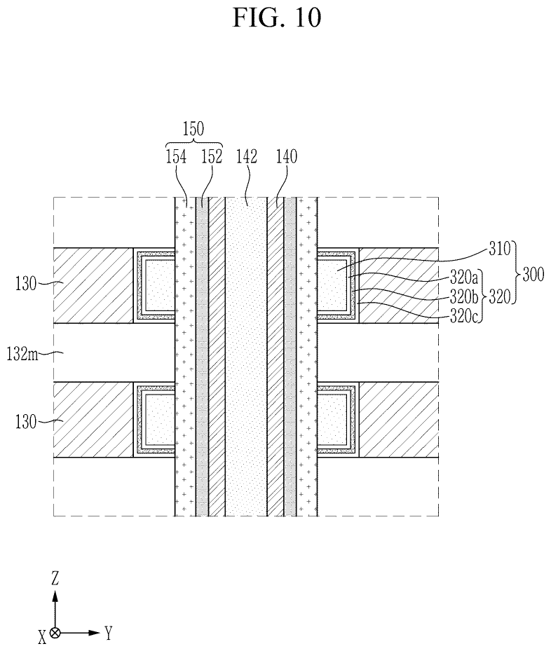

FIG. 10 is a cross-sectional view of a region S1 of a semiconductor device shown in FIG. 2 according to several embodiments.

A semiconductor device according to an embodiment of FIG. 10 mostly corresponds to a semiconductor device according to an embodiment of FIG. 1 to FIG. 7 so repeated descriptions thereof may be omitted and the differences will be mainly described. In addition, the same or similar reference numerals may be used for constituent elements that are identical or similar to those of a previous embodiment. A present embodiment differs from a previous embodiment in that the insulation pattern 320 has a multilayer structure, which will be described below.

Referring to FIG. 1 and FIG. 10, in an embodiment, the cell region 100 of the semiconductor device 10 includes a second substrate 110, a gate stacking structure 120 disposed on the second substrate 110, a channel structure CH that penetrates the gate stacking structure 120 and includes a channel layer 140 and a ferroelectric layer 154, and a gate dielectric pattern 300 that surrounds at least a portion of the ferroelectric layer 154.

In a previous embodiment, the insulation pattern 320 includes the first portion 321, the second portion 322, and the third portion 323 that are sequentially disposed from the exterior side of the ferroelectric layer 154.

Referring to FIG. 10, in an embodiment, the insulation pattern 320 of the semiconductor device 10 includes a first insulation pattern 320a, a second insulation pattern 320b, and a third insulation pattern 320c that are sequentially disposed from the exterior side of the ferroelectric layer 154.

The first insulation pattern 320a surrounds at least a portion of the charge inflow pattern 310. For example, the first insulation pattern 320a surrounds the upper side 310U, the lower side 310B, and the exterior side 310S of the charge inflow pattern 310. For example, the first insulation pattern 320a is disposed on the upper side of the charge inflow pattern 310, the lower side of the charge inflow pattern 310, and the exterior side of the charge inflow pattern 310. The first insulation pattern 320a is disposed between the charge inflow pattern 310 and the second insulation pattern 320b. The first insulation pattern 320a directly contacts the charge inflow pattern 310 and the second insulation pattern 320b.

The first insulation pattern 320a extends in the circumferential direction of the channel structure CH. For example, the first insulation pattern 320a covers the upper side, the lower side, and the exterior side of the charge inflow pattern 310. For example, the portion of the first insulation pattern 320a disposed on the upper side and the lower side of the charge inflow pattern 310 and the portion of the first insulation pattern 320a disposed on the exterior side of the charge inflow pattern 310 extend in the circumferential direction of the channel structure CH.

In an embodiment, the first insulation pattern 320a includes one or more of various types of insulating materials. For example, the first insulation pattern 320a includes silicon oxide (SiO₂). However, without being necessarily limited thereto, the first insulation pattern 320a includes at least one of silicon nitride (SiN), silicon oxynitride (SiON), silicon oxycarbide (SiOC), silicon oxycarbonitride (SiOCN), or silicon carbonitride (SiCN).

The second insulation pattern 320b surrounds the first insulation pattern 320a. For example, the second insulation pattern 320b surrounds the upper side, the lower side, and the exterior side of the first insulation pattern 320a. For example, the second insulation pattern 320b is disposed on the upper side, the lower side, and the exterior side of the first insulation pattern 320a. The second insulation pattern 320b is disposed between the first insulation pattern 320a and the third insulation pattern 320c. The second insulation pattern 320b directly contacts the first insulation pattern 320a and the third insulation pattern 320c.

In an embodiment, the second insulation pattern 320b includes an insulating material that differs from that of the first insulation pattern 320a. For example, the second insulation pattern 320b includes at least one of silicon nitride (SiN), silicon oxynitride (SiON), silicon oxycarbide (SiOC), silicon oxycarbonitride (SiOCN), or silicon carbonitride (SiCN).

The third insulation pattern 320c surrounds the second insulation pattern 320b. For example, the third insulation pattern 320c surrounds the upper side, the lower side, and the exterior side of the second insulation pattern 320b. For example, the third insulation pattern 320c is disposed on the upper side, the lower side, and the exterior side of the second insulation pattern 320b. The third insulation pattern 320c is disposed between the second insulation pattern 320b and the gate electrodes 130 and between the second insulation pattern 320b and the interlayer insulating layers 132m. The third insulation pattern 320c directly contacts the second insulation pattern 320b, the gate electrodes 130, and the interlayer insulating layers 132m.

In an embodiment, the third insulation pattern 320c includes one or more of various types of insulating materials. The third insulation pattern 320c includes a material that differs from that of the second insulation pattern 320b. For example, the third insulation pattern 320c includes silicon oxide (SiO₂). However, without being necessarily limited thereto, the third insulation pattern 320c includes at least one of silicon nitride (SiN), silicon oxynitride (SiON), silicon oxycarbide (SiOC), silicon oxycarbonitride (SiOCN), or silicon carbonitride (SiCN).

In the semiconductor device 10, an electric field is generated in the charge inflow pattern 310 according to a voltage applied to the gate electrodes 130. Hence, charge can easily flow into the charge inflow pattern 310, and a residual polarization is easily generated in the ferroelectric layer 154. For example, when a voltage applied to the gate electrodes 130 is reduced, the electric field is generated in the charge inflow pattern 310 and the residual polarization is easily generated in the ferroelectric layer 154.

Further, since the second insulation pattern 320b of the semiconductor device 10 includes silicon nitride (SiN), when a voltage is applied to the gate electrodes 130, the electric field is easily generated in the charge inflow pattern 310 according to the dopant concentration. Therefore, charge can easily flow into the charge inflow pattern 310, and hence, residual polarization is easily generated in the ferroelectric layer 154. For example, an operating voltage that generates the residual polarization in the ferroelectric layer 154 is reduced, and reliability of the semiconductor device 10 is increased.

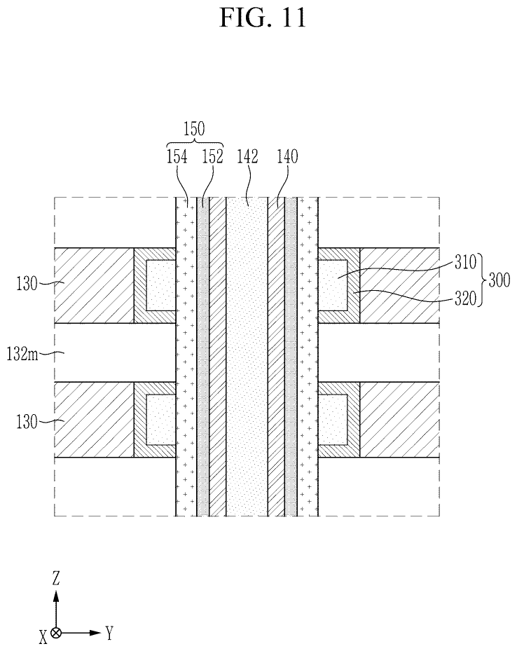

FIG. 11 is a cross-sectional view on a region S1 of a semiconductor device shown in FIG. 2 according to several embodiments.

A semiconductor device according to an embodiment of FIG. 11 mostly corresponds to a semiconductor device according to an embodiment of FIG. 1 to FIG. 7, so that a repeated description thereof will be omitted and the differences will be mainly described. In addition, the same or similar reference numerals may be used for constituent elements that are identical or similar to those of a previous embodiment. A present embodiment differs from a previous embodiment in that the insulation pattern 320 has a single layer, which will be described below.

Referring to FIG. 1 and FIG. 11, in an embodiment, the cell region 100 of the semiconductor device 10 includes a second substrate 110, a gate stacking structure 120 disposed on the second substrate 110, a channel structure CH that penetrates the gate stacking structure 120 and includes a channel layer 140 and a ferroelectric layer 154, and a gate dielectric pattern 300 disposed on the lateral side of the ferroelectric layer 154.

In a previous embodiment, the insulation pattern 320 includes the first portion 321, the second portion 322, and the third portion 323 that are sequentially disposed on the exterior side of the ferroelectric layer 154.

Referring to FIG. 11, in an embodiment, the insulation pattern 320 of the semiconductor device 10 has a single layer.

For example, the insulation pattern 320 surrounds at least a portion of the charge inflow pattern 310. For example, the insulation pattern 320 surrounds the upper side, the lower side, and the exterior side of the charge inflow pattern 310. For example, the insulation pattern 320 is disposed on the upper side of the charge inflow pattern 310, the lower side of the charge inflow pattern 310, and the exterior side of the charge inflow pattern 310.

In an embodiment, the insulation pattern 320 includes one or more of various types of insulating materials. For example, the insulation pattern 320 includes silicon oxide (SiO₂). However, without being necessarily limited thereto, the insulation pattern 320 includes at least one of silicon nitride (SiN), silicon oxynitride (SiON), silicon oxycarbide (SiOC), silicon oxycarbonitride (SiOCN), or silicon carbonitride (SiCN).

In the semiconductor device 10, the electric field is generated in the charge inflow pattern 310 according to a voltage applied to the gate electrodes 130. Hence, charge can easily flow into the charge inflow pattern 310, and a residual polarization can be easily generated in the ferroelectric layer 154. For example, when a voltage applied to the gate electrodes 130 is reduced, the electric field is generated in the charge inflow pattern 310 and the residual polarization is easily generated in the ferroelectric layer 154.

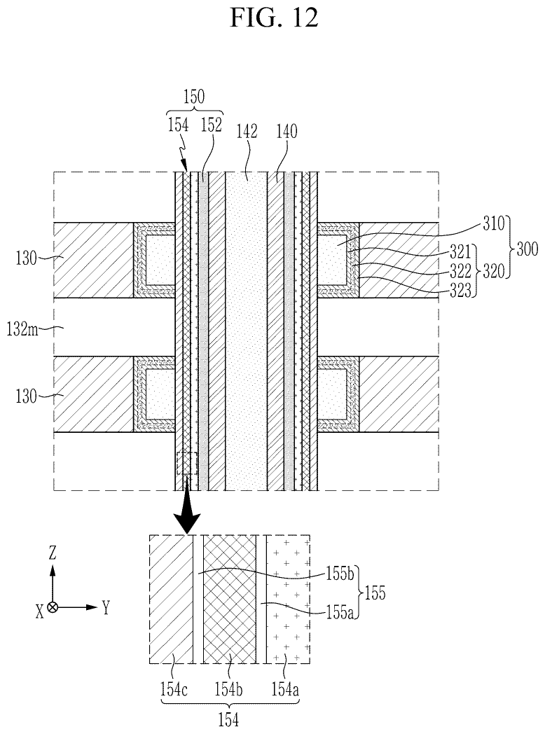

FIG. 12 is a cross-sectional view on a region S1 of a semiconductor device shown in FIG. 2 according to several embodiments.

A semiconductor device according to an embodiment shown in FIG. 12 mostly corresponds to a semiconductor device according to an embodiment shown in FIG. 1 to FIG. 7 so a repeated description thereof may be omitted and the differences will be mainly described. In addition, the same or similar reference numerals may be used for constituent elements that are identical or similar to those of a previous embodiment. The present embodiment differs from a previous embodiment in that the ferroelectric layer 154 has a multilayer structure, which will be described below.

Referring to FIG. 1 and FIG. 12, in an embodiment, the cell region 100 of the semiconductor device 10 includes a second substrate 110, a gate stacking structure 120 disposed on the second substrate 110, a channel structure CH that penetrates the gate stacking structure 120 and includes a channel layer 140 and a ferroelectric layer 154, and a gate dielectric pattern 300 disposed on the lateral side of the ferroelectric layer 154.

Referring to FIG. 12, in an embodiment, the ferroelectric layer 154 has a multilayer structure.

For example, the ferroelectric layer 154 includes first to third ferroelectric patterns 154a, 154b, and 154c. The first to third ferroelectric patterns 154a, 154b, and 154c sequentially surround the lateral side of the channel insulation layer 152.

The first to third ferroelectric patterns 154a, 154b, and 154c sequentially surround the channel insulation layer 152. For example, the first ferroelectric pattern 154a surrounds the channel insulation layer 152. The second ferroelectric pattern 154b surrounds the first ferroelectric pattern 154a. The third ferroelectric pattern 154c surrounds the second ferroelectric pattern 154b. The first to third ferroelectric patterns 154a, 154b, and 154c extend in the third direction (Z direction). The first to third ferroelectric patterns 154a, 154b, and 154c have an annular shape in a plan view. The first to third ferroelectric patterns 154a, 154b, and 154c are disposed between the channel insulation layer 152 and the gate dielectric pattern 300, and between the channel insulation layer 152 and the interlayer insulating layers 132m.

At least one of the first to third ferroelectric patterns 154a, 154b, and 154c includes a ferroelectric material. For example, the ferroelectric layer 154 includes a ferroelectric Hf compound. For example, the ferroelectric layer 154 includes at least one of HfO₂, HfZnO, HfSiO, HfSiON, HfTaO, HfTiO, HfZrO or combinations thereof.

In an embodiment, the ferroelectric layer 154 includes interface inserting films 155 disposed between the first to third ferroelectric patterns 154a, 154b, and 154c. For example, the ferroelectric layer 154 further includes a first interface inserting film 155a disposed between the first ferroelectric pattern 154a and the second ferroelectric pattern 154b, and a second interface inserting film 155b disposed between the second ferroelectric pattern 154b and the third ferroelectric pattern 154c.

The first interface inserting film 155a surrounds the first ferroelectric pattern 154a. The first interface inserting film 155a extends in the third direction (Z direction). The second interface inserting film 155b surrounds the second ferroelectric pattern 154b. The second interface inserting film 155b extends in the third direction (Z direction). The first interface inserting film 155a and the second interface inserting film 155b are spaced apart in the radial direction of the channel structure CH.

The interface inserting films 155a and 155bs include insulating materials. For example, the interface inserting films 155a and 155b include at least one of aluminum oxide (Al₂O₃), silicon oxide (SiO₂), or HfSiO.

In an embodiment, when the first to third ferroelectric patterns 154a, 154b, and 154c and the interface inserting films 155a and 155b include HfSiO, a concentration of the silicon (Si) in the interface inserting films 155a and 155b is greater than the concentration of the silicon (Si) in the first to third ferroelectric patterns 154a, 154b, and 154c. In an embodiment, when the concentration of the silicon (Si) in the interface inserting films 155a and 155bs is high, the interface inserting films 155a and 155bs function as an insulation layer between the first to third ferroelectric patterns 154a, 154b, and 154c. The concentration of the silicon (Si) in the interface inserting films 155a and 155b refers to a content of the element of silicon (Si) in the interface inserting films 155a and 155b.

FIG. 12 shows that the ferroelectric layer 154 includes three dielectric material layers, but is not necessarily limited thereto. For example, in some embodiments, the ferroelectric layer 154 includes one or two dielectric material layers. In some embodiments, the ferroelectric layer 154 includes at least four dielectric material layers.

FIG. 13 is a cross-sectional view of a region S1 of a semiconductor device of FIG. 2 according to several embodiments.

A semiconductor device according to an embodiment of FIG. 13 mostly corresponds to a semiconductor device according to an embodiment of FIG. 1 to FIG. 7, so that a repeated description thereof may be omitted and the differences will be mainly described. In addition, the same or similar reference numerals may be used for constituent elements that are identical or similar to those of a previous embodiment. A present embodiment differs from a previous embodiment in that the shape of the ferroelectric layer 154 and the shape of the charge inflow pattern 310 differ from those of a previous embodiment, which will be described below.

Referring to FIG. 1 and FIG. 13, in an embodiment, the cell region 100 of the semiconductor device 10 includes a second substrate 110, a gate stacking structure 120 disposed on the second substrate 110, a channel structure CH that penetrates the gate stacking structure 120 and includes a channel layer 140 and a ferroelectric layer 154, and a gate dielectric pattern 300 that surrounds at least a portion of the ferroelectric layer 154.

Referring to FIG. 13, the ferroelectric layers 154 are disposed and spaced apart in the third direction (Z direction). For example, a plurality of the ferroelectric layers 154 are provided so that they can be spaced apart at predetermined intervals in the third direction (Z direction). The spaced apart ferroelectric layers 154 surround the channel insulation layers 152. Hence, at least a portion of the channel insulation layer 152 is surrounded by the interlayer insulating layers 132m. At least a portion of the channel insulation layer 152 directly contacts the interlayer insulating layers 132m.

The gate dielectric pattern 300 of the semiconductor device 10 includes a tunneling layer 330, a charge inflow pattern 310, and an insulation pattern 320 that are sequentially disposed on the ferroelectric layer 154.

The tunneling layer 330 surrounds at least a portion of the ferroelectric layer 154. For example, the tunneling layer 330 surrounds the upper side, the lower side, and the exterior side of the ferroelectric layer 154. For example, the tunneling layer 330 is disposed on the upper side of the ferroelectric layer 154, the lower side of the ferroelectric layer 154, and the exterior side of the ferroelectric layer 154. The tunneling layer 330 is disposed between the ferroelectric layer 154 and the charge inflow pattern 310. The tunneling layer 330 directly contacts the ferroelectric layer 154 and the charge inflow pattern 310.

In an embodiment, the tunneling layer 330 extends in the circumferential direction of the channel structure CH. For example, the tunneling layer 330 covers the upper side, the lower side, and the exterior side of the ferroelectric layer 154. For example, a portion of the tunneling layer 330 disposed on the upper side and the lower side of the ferroelectric layer 154 and a portion of the tunneling layer 330 disposed on the exterior side of the ferroelectric layer 154 extend in the circumferential direction of the channel structure CH.

The charge inflow pattern 310 surrounds the tunneling layer 330. For example, the charge inflow pattern 310 surrounds the upper side, the lower side, and the exterior side of the tunneling layer 330. For example, the charge inflow pattern 310 is disposed on an upper side of the tunneling layer 330, a lower side of the tunneling layer 330, and an exterior side of the tunneling layer 330. The charge inflow pattern 310 is disposed between the tunneling layer 330 and the insulation pattern 320. The charge inflow pattern 310 directly contacts the tunneling layer 330 and the insulation pattern 320.

In an embodiment, the charge inflow pattern 310 extends in the circumferential direction of the channel structure CH. For example, the charge inflow pattern 310 covers the upper side, the lower side, and the exterior side of the tunneling layer 330. For example, a portion of the charge inflow pattern 310 disposed on the upper side and the lower side of the tunneling layer 330 and a portion of the charge inflow pattern 310 disposed on the exterior side of the tunneling layer 330 extends in the circumferential direction of the channel structure CH.

In an embodiment, a first length D11 of the charge inflow pattern 310 that extends in the third direction (Z direction) is less than second widths W2 of the gate electrodes 130 in the third direction (Z direction). Therefore, the charge inflow pattern 310 overlaps the gate electrodes 130 in the radial direction of the channel structure CH, but does not overlap the interlayer insulating layers 132m in the radial direction of the channel structure CH.

The insulation pattern 320 surrounds the charge inflow pattern 310. For example, the insulation pattern 320 surrounds the upper side, the lower side, and the exterior side of the charge inflow pattern 310. For example, the insulation pattern 320 is disposed on the upper side of the charge inflow pattern 310, the lower side of the charge inflow pattern 310, and the exterior side of the charge inflow pattern 310. The insulation pattern 320 is disposed between the charge inflow pattern 310 and the gate electrodes 130, and between the charge inflow pattern 310 and the interlayer insulating layers 132m. The insulation pattern 320 directly contacts the gate electrodes 130 and the interlayer insulating layers 132m.

In an embodiment, the insulation pattern 320 extends in the circumferential direction of the channel structure CH. For example, the insulation pattern 320 covers the upper side, the lower side, and the exterior side of the charge inflow pattern 310. For example, a portion of the insulation pattern 320 disposed on the upper side and the lower side of the charge inflow pattern 310 and a portion of the insulation pattern 320 disposed on the exterior side of the charge inflow pattern 310 extend in the circumferential direction of the channel structure CH.

In the semiconductor device 10, since the charge inflow pattern 310 surrounds the upper side, the lower side, and the exterior side of the ferroelectric layer 154, an electric field is generated in the charge inflow pattern 310 according to a voltage applied to the gate electrodes 130. Hence, charge easily flows into the charge inflow pattern 310, and the residual polarization is easily generated in the ferroelectric layer 154. For example, when a voltage applied to the gate electrodes 130 is reduced, the electric field is generated in the charge inflow pattern 310 and the residual polarization is easily generated in the ferroelectric layer 154.

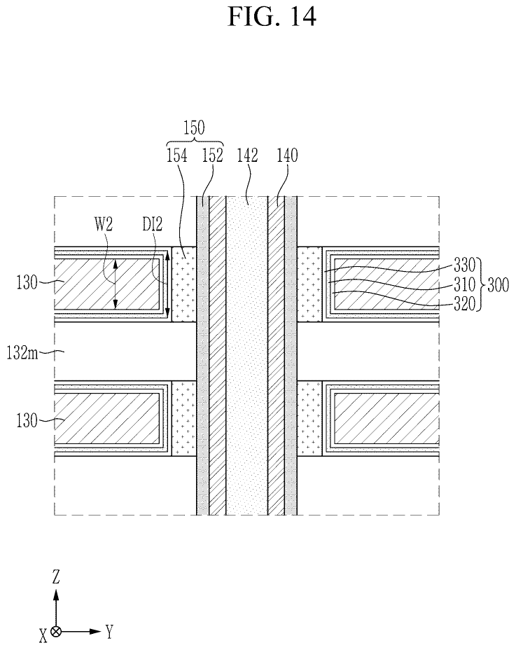

FIG. 14 is a cross-sectional view on a region S1 of a semiconductor device shown in FIG. 2 according to several embodiments.

A semiconductor device according to an embodiment shown in FIG. 14 mostly corresponds to a semiconductor device according to an embodiment of FIG. 1 to FIG. 7, so that repeated descriptions thereof may be omitted and the differences will be mainly described. In addition, the same or similar reference numerals may be used for constituent elements that are identical or similar to those of a previous embodiment. A present embodiment differs from a previous embodiment in that the shape of the ferroelectric layer 154 and the shape of the charge inflow pattern 310 differ from those of a previous embodiment, which will be described below.

Referring to FIG. 1 and FIG. 14, in an embodiment, the cell region 100 of the semiconductor device 10 includes a second substrate 110, a gate stacking structure 120 disposed on the second substrate 110, a channel structure CH that penetrates the gate stacking structure 120 and includes a channel layer 140 and a ferroelectric layer 154, and a gate dielectric pattern 300 disposed on the lateral side of the ferroelectric layer 154.

Referring to FIG. 14, the ferroelectric layers 154 are disposed and spaced apart in the third direction (Z direction). For example, a plurality of the ferroelectric layers 154 are provided so that they can be spaced apart from each other at predetermined intervals in the third direction (Z direction). The respective ferroelectric layers 154 spaced apart in the third direction (Z direction) surround the channel insulation layer 152. Hence, at least a portion of the channel insulation layer 152 is surrounded by the interlayer insulating layers 132m. At least a portion of the channel insulation layer 152 directly contacts the interlayer insulating layers 132m. However, without being necessarily limited thereto, similar to embodiments shown in FIG. 7 to FIG. 12, the ferroelectric layer 154 may extend continuously in the third direction (Z direction) and surround the channel insulation layer 152.

The gate dielectric pattern 300 of the semiconductor device 10 includes an insulation pattern 320, a charge inflow pattern 310, and a tunneling layer 330 that are sequentially disposed on the gate electrodes 130.

The insulation pattern 320 surrounds at least a portion of the gate electrodes 130. For example, the insulation pattern 320 surrounds the upper sides, the lower sides, and one lateral side of the gate electrodes 130. For example, the insulation pattern 320 is disposed on the upper sides of the gate electrodes 130, the lower sides of the gate electrodes, and one lateral side of the gate electrodes 130. The insulation pattern 320 is disposed between the gate electrodes 130 and the charge inflow pattern 310. The insulation pattern 320 directly contacts the gate electrodes 130 and the charge inflow pattern 310.

The charge inflow pattern 310 surrounds the insulation pattern 320. For example, the charge inflow pattern 310 surrounds the upper side, the lower side, and the exterior side of the insulation pattern 320. For example, the charge inflow pattern 310 is disposed on the upper side of the insulation pattern 320, the lower side of the channel insulation layer, and the exterior side of the insulation pattern 320. The charge inflow pattern 310 is disposed between the insulation pattern 320 and the tunneling layer 330. The charge inflow pattern 310 directly contact the insulation pattern 320 and the tunneling layer 330. In an embodiment, a second length D12 of the charge inflow pattern 310 in the third direction (Z direction) is less than a second width W2 of the gate electrodes 130 in the third direction (Z direction).

The tunneling layer 330 surrounds the charge inflow pattern 310. For example, the tunneling layer 330 surrounds the upper side, the lower side, and the exterior side of the charge inflow pattern 310. For example, the tunneling layer 330 is disposed on the upper side of the charge inflow pattern 310, the lower side of the charge inflow pattern, and the exterior side of the charge inflow pattern 310. The tunneling layer 330 is disposed between the charge inflow pattern 310 and the ferroelectric layer 154 and between the charge inflow pattern 310 and the interlayer insulating layers 132m. The tunneling layer 330 directly contacts the ferroelectric layer 154 and the interlayer insulating layers 132m.

In the semiconductor device 10, since the charge inflow pattern 310 is disposed between the gate electrodes 130 and the ferroelectric layer 154, an electric field is generated in the charge inflow pattern 310 according to a voltage applied to the gate electrodes 130. Hence, charge easily flows into the charge inflow pattern 310, and the residual polarization is easily generated in the ferroelectric layer 154. For example, when a voltage applied to the gate electrodes 130 is reduced, the electric field is generated in the charge inflow pattern 310 and the residual polarization is easily generated in the ferroelectric layer 154.

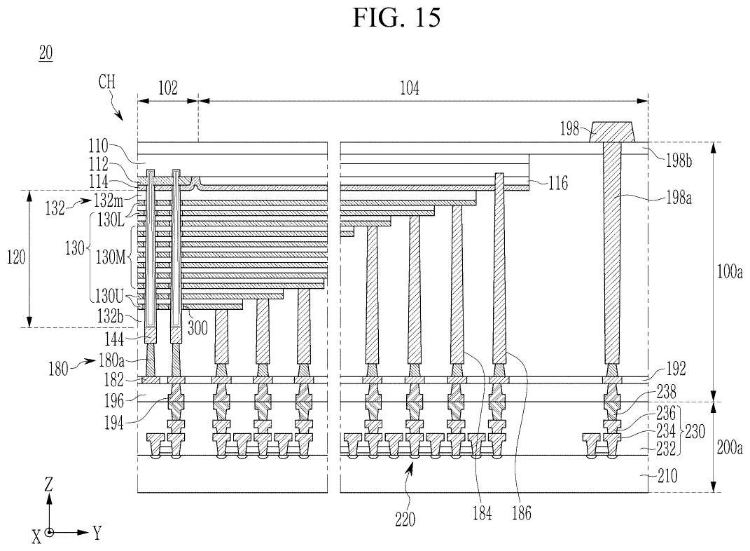

A semiconductor device according to several embodiments will now be described with reference to FIG. 15.

FIG. 15 is a cross-sectional view of a semiconductor device according to several embodiments.

An embodiment shown in FIG. 15 mostly corresponds to embodiments of FIG. 1 to FIG. 14, so that a repeated description thereof may be omitted and the differences will be mainly described. In addition, the same or similar reference numerals may be used for constituent elements that are identical or similar to those of the previous embodiment.

Referring to FIG. 15, in an embodiment, the semiconductor device 20 has a chip to chip (C2C) structure bonded by a wafer bonding method. For example, the semiconductor device 20 is manufactured by manufacturing a lower chip that includes a circuit region 200a formed on the first substrate 210, manufacturing an upper chip that includes a cell region 100a formed on the second substrate 110, and bonding them.

The circuit region 200a includes a first junction structure 238 on the first substrate 210, the circuit element 220, and the first wire portion 230, and on a side that faces the cell region 100a.

The cell region 100a includes a second junction structure 194 on the second substrate 110, the gate stacking structure 120, the channel structure CH, and the second wire portion 180 and on a side facing the circuit region 200a.

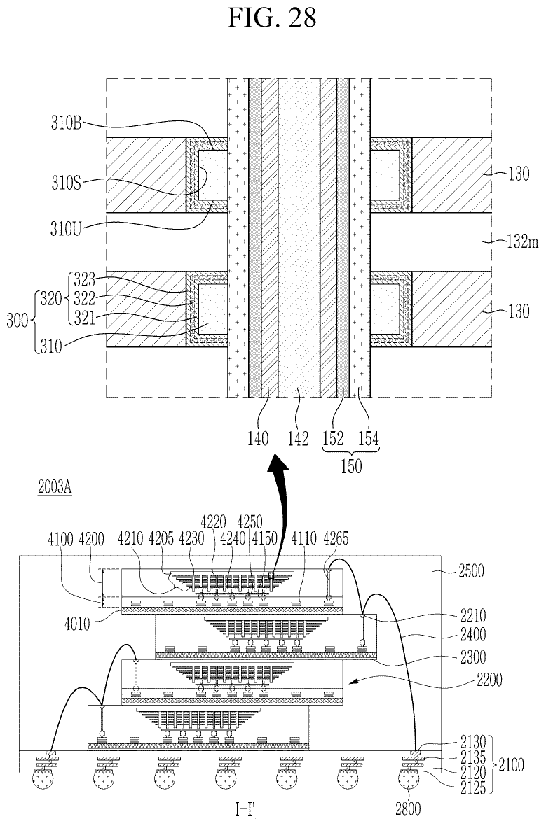

Regarding the gate stacking structure 120, the gate electrodes 130 include a lower gate electrode 130L, a memory cell gate electrode 130M, and an upper gate electrode 130U that faces the circuit region 200a from the second substrate 110 and that are sequentially disposed on the second substrate 110. For example, as shown in FIG. 28, the gate stacking structure 120 is sequentially stacked on a lower portion of the second substrate 110, and the gate stacking structure 120 shown in FIG. 1 to FIG. 14 is disposed while reversed upside down.

Hence, the channel pad 144 and the second wire portion 180 disposed on the gate stacking structure 120 are disposed near the circuit region 200a. The second junction structure 194 electrically connected to the second wire portion 180 is disposed on a side that faces the circuit region 200a. A region that is exclusive of the second junction structure 194 is covered by the insulation layer 196. The second wire portion 180 and the second junction structure 194 are disposed to face the circuit region 200a in the cell region 100a.

The second junction structure 194 of the cell region 100a and the first junction structure 238 of the circuit region 200a include at least one of aluminum, copper, tungsten, or alloys thereof. For example, the first and second junction structures 238 and 194 include copper, and the cell region 100a and the circuit region 200a are connected by a copper-to-copper junction. For example, the cell region 100a and the circuit region 200a directly contact each other and are bonded to each other.

FIG. 15 shows that the gate stacking structure 120 is a single gate stacking structure, but as is shown in FIG. 1, it can include multiple gate stacking structures. Except for what is additionally described, the structures of the gate stacking structure 120 and the channel structure CH are substantially the same as those described with reference to FIG. 1 to FIG. 14.

The semiconductor device 20 includes an input/output pad 198 and an input/output connecting wire 198a electrically connected thereto. The input/output connecting wire 198a is electrically connected to a portion of the second junction structure 194. The input/output pad 198 is, for example, disposed on an insulation layer 198b that covers an external side of the second substrate 110. Depending on embodiments, an additional input/output pad electrically connected to the circuit region 200a may be provided.

In an embodiment, the circuit region 200a and the cell region 100a correspond to the first structure 1100F and the second structure 1100S of the semiconductor device 1100 in the electronic system 1000 shown in FIG. 25. In an embodiment, the circuit region 200a and the cell region 100a correspond to a first structure 4100 and a second structure 4200 of the semiconductor chip 2200 shown in FIG. 28.

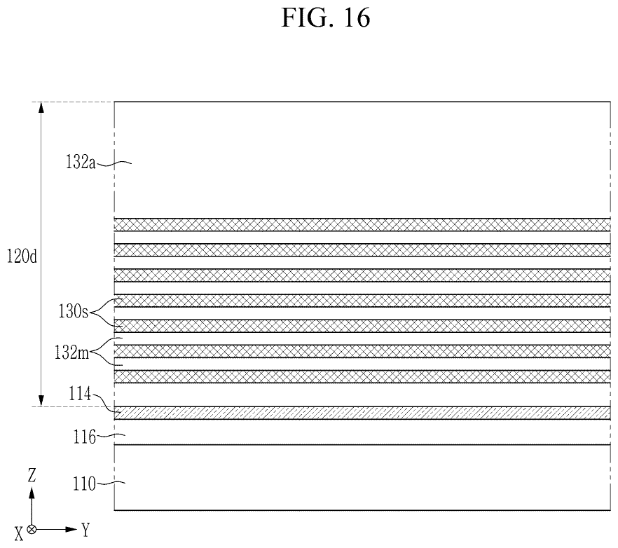

A method for manufacturing a semiconductor device according to an embodiment will now be described with reference to FIG. 16 to FIG. 24.

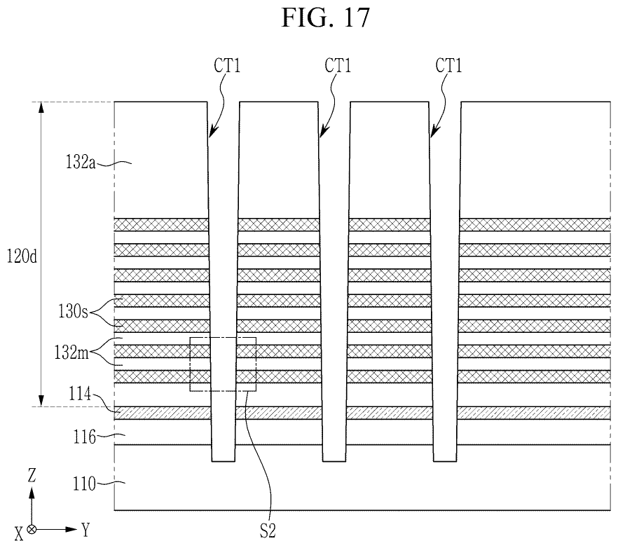

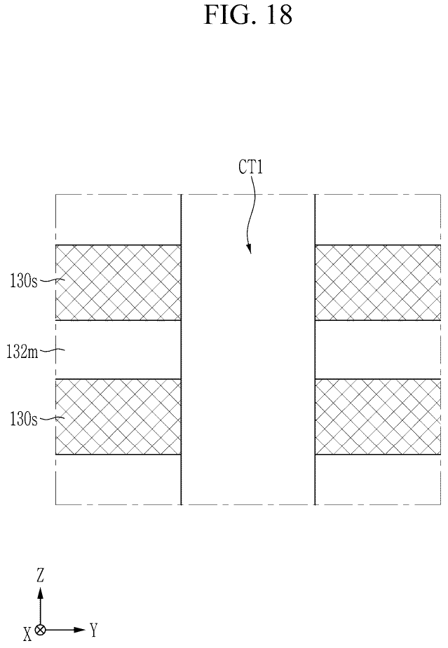

FIG. 16 and FIG. 17 are cross-sectional views that illustrate an intermediate stage of a method for manufacturing a semiconductor device according to an embodiment. FIG. 18 to FIG. 24 are cross-sectional views of a region S2 of FIG. 17 in a method for manufacturing a semiconductor device according to an embodiment. FIG. 16 to FIG. 24 illustrate intermediate processes of a method for manufacturing a semiconductor device according to an embodiment.

For ease of illustration, FIG. 16 and FIG. 17 show the cell structure, but not the circuit region that includes a peripheral circuit region. FIG. 16 and FIG. 17 show that the stacking structure 120d is a single stacking structure, but embodiments are not necessarily limited thereto, and in other embodiments, include at least two stacking structures. A method for manufacturing a gate dielectric pattern 300 of a semiconductor device according to an embodiment will now be described.

Referring to FIG. 16, in an embodiment, a horizontal insulation layer 116 and a second horizontal conductive layer 114 are stacked on the second substrate 110, and a stacking structure 120d is formed on the second horizontal conductive layer 114. A circuit region is formed below the second substrate 110, but the circuit region is not shown. For example, the circuit region is formed, and the second substrate 110 is then formed in the circuit region. However, without being necessarily limited thereto, the structure below the second substrate 110 and the method for forming it can be modified in many ways.

A horizontal insulation layer 116 is formed on the second substrate 110 by using an insulating material. The second substrate 110 includes a semiconductor material, such as polysilicon. For example, the second substrate 110 includes impurity-doped polysilicon. However, the material of the second substrate 110 is not necessarily limited thereto, and can be changed in many ways. For example, the second substrate 110 can include a conductive material or a metal silicide.

The horizontal insulation layer 116 may be a single layer or have a multilayer structure. For example, the horizontal insulation layer 116 is formed by sequentially stacking a silicon oxide, a silicon nitride, and a silicon oxide.

At least a portion of the horizontal insulation layer 116 is replaced with a first horizontal conductive layer 112 of FIG. 1 in a subsequent process. For example, the horizontal insulation layer 116 is formed to include a portion on which the first horizontal conductive layer 112 of FIG. 1 is formed. In an embodiment, the horizontal insulation layer 116 includes layers sequentially stacked on the second substrate 110, but embodiments are not necessarily limited thereto.

A second horizontal conductive layer 114 is formed on the horizontal insulation layer 116. The second horizontal conductive layer 114 is formed by using a semiconductor material, such as polysilicon. For example, the second horizontal conductive layer 114 includes impurity-doped polysilicon.

The interlayer insulating layers 132m and the sacrificial insulation layers 130s are alternately stacked on the second horizontal conductive layer 114 to form a stacking structure 120d. When the interlayer insulating layers 132m and the sacrificial insulation layers 130s are alternately stacked, a first upper insulation layer 132a is formed on the uppermost portion.

The sacrificial insulation layer 130s includes at least one of silicon oxide, silicon nitride, silicon oxynitride, or a low dielectric material. The sacrificial insulation layers 130s include materials that differ from those of the interlayer insulating layers 132m. The sacrificial insulation layers 130s include materials that have etch selectivity with respect to the interlayer insulating layers 132m. For example, the sacrificial insulation layers 130s include at least one of silicon, silicon oxide, silicon carbide, or silicon nitride, and include materials that differ from those of the interlayer insulating layers 132m. For example, the interlayer insulating layers 132m include silicon oxide, and the sacrificial insulation layers 130s include silicon nitride. The sacrificial insulation layers 130s are replaced with the gate electrode 130 of FIG. 1 in a subsequent process. For example, the sacrificial insulation layers 130s correspond to portions where the gate electrode 130 of FIG. 1 will be formed.

The stacking structure 120d is shown as a single stacking structure, but without being necessarily limited thereto, the stacking structure 120d can include at least two stacking structures.

Referring to FIG. 17 and FIG. 18, in an embodiment, a first channel hole CT1 is formed by patterning the stacking structure 120d. The stacking structure 120d is penetrated by the first channel hole CT1. During a process of patterning the stacking structure 120d, the horizontal insulation layer 116 and the second substrate 110 are patterned.

The first channel hole CT1 penetrates through the horizontal insulation layer 116 and into the second substrate 110. However, a depth of the first channel hole CT1 formed in the second substrate 110 is less than the thickness of the second substrate 110. Hence, the lateral sides of the sacrificial insulation layers 130s and the interlayer insulating layers 132m are exposed.

Referring to FIG. 19, in an embodiment, a gate dielectric recess 300R is formed by etching a portion of the exposed sacrificial insulation layers 130s.

In an embodiment, a process of etching a portion of the sacrificial insulation layers 130s includes using a dry etching process, but embodiments are not necessarily limited thereto. As described above, since the sacrificial insulation layers 130s include materials that are etch selective with respect to the interlayer insulating layers 132m, the interlayer insulating layers 132m are not etched in a process for etching the sacrificial insulation layers 130s. Hence, the gate dielectric recess 300R is formed between the interlayer insulating layers 132m. The width of the gate dielectric recess 300R in the third direction (Z direction) is equal to the width of the sacrificial insulation layers 130s in the third direction (Z direction).

The gate dielectric recess 300R extends in the radial direction of the first channel hole CT1 from the internal sidewall of the first channel hole CT1. For example, as shown in FIG. 19, the gate dielectric recess 300R extends in the second direction (Y direction) from the internal sidewall of the first channel hole CT1. While the gate dielectric recess 300R is being formed, a portion of the upper side and a portion of the lower side of the interlayer insulating layers 132m are exposed.

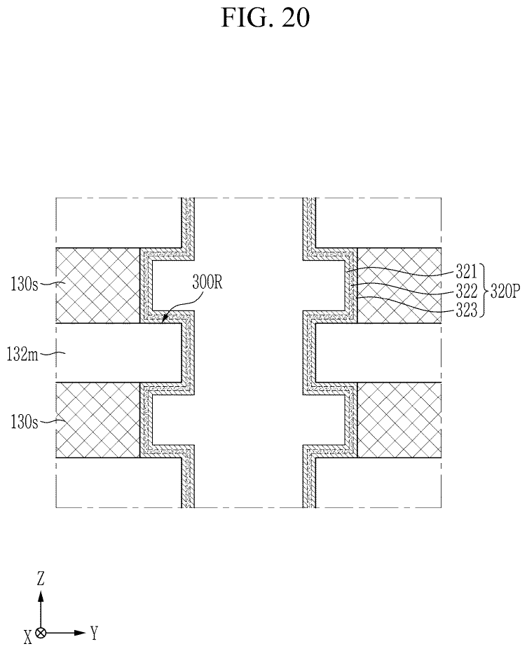

Referring to FIG. 20, in an embodiment, a preliminary insulation pattern 320P is formed in the gate dielectric recess 300R.

The preliminary insulation pattern 320P is formed on the internal sidewall of the first channel hole CT1 and the gate dielectric recess 300R. For example, the preliminary insulation pattern 320P is conformally formed on a portion of the upper side and a portion of the lower side of the interlayer insulating layers 132m exposed by the lateral sides of the interlayer insulating layers 132m and the gate dielectric recess 300R. Hence, the preliminary insulation pattern 320P includes a portion that extends in the third direction (Z direction) and that is formed on the lateral sides of the interlayer insulating layers 132m and a portion formed in the gate dielectric recess 300R.

In an embodiment, the first to third portions 321 to 323 of the preliminary insulation pattern 320P are sequentially formed in the gate dielectric recess 300R.

For example, the first portion 321 of the preliminary insulation pattern 320P is formed in the internal sidewall of the first channel hole CT1 and the gate dielectric recess 300R. For example, the first portion 321 of the preliminary insulation pattern 320P is conformally formed on a portion of the upper side and a portion of the lower side of the interlayer insulating layers 132m exposed by the lateral side of the interlayer insulating layers 132m and the gate dielectric recess 300R. The second portion 322 is formed on the lateral side of the first portion 321, and the third portion 323 is formed on the lateral side of the second portion 322.

In an embodiment, the first to third portions 321 to 323 include one or more of various types of insulating materials. For example, the first to third portions 323 include silicon oxide (SiO₂). However, without being necessarily limited thereto, the first to third portions 323 include at least one of silicon nitride (SiN), silicon oxynitride (SiON), silicon oxycarbide (SiOC), silicon oxycarbonitride (SiOCN), or silicon carbonitride (SiCN).

In an embodiment, a predetermined dopant is doped into at least one of the first to third portions 321 to 323. For example, the dopant includes nitrogen (N), but is not necessarily limited thereto. A process of doping a predetermined dopant into at least one of the first to third portions 321 to 323 includes forming one of the first to third portions 321 to 323 and doping a dopant into the formed portion. However, without being necessarily limited thereto, the preliminary insulation pattern 320P can be formed by respectively depositing in the gate dielectric recess 300R the first to third portions 321 to 323 of the preliminary insulation pattern 320P into which a predetermined dopant is doped.

The dopant concentration of the insulation pattern 320 includes a portion that decreases with an increasing distance from the charge inflow pattern 310. For example, similar to an embodiment of FIG. 6, the dopant concentration of the insulation pattern 320 increases and then decreases with increasing distance from the charge inflow pattern 310. In an embodiment of FIG. 7, the dopant concentration of the insulation pattern 320 monotonically decreases with increasing distance from the charge inflow pattern 310.

However, in some embodiments, without being necessarily limited thereto, the preliminary insulation pattern 320P includes first to third insulation patterns 320a to 320c that include different materials, similar to an embodiment of FIG. 10. For example, the first insulation pattern 320a and the third insulation pattern 320c include one or more of various types of insulating materials, such as silicon oxide (SiO₂), and the second insulation pattern 320b includes silicon nitride (SiN), which differs from a material of the first insulation pattern 320a and the third insulation pattern 320c. In some embodiments, similar to an embodiment of FIG. 11, the preliminary insulation pattern 320P has a single layer.

Referring to FIG. 21, in an embodiment, the preliminary charge inflow pattern 310P is formed on the lateral side of the preliminary insulation pattern 320P.

For example, the preliminary charge inflow pattern 310P is formed on the portion of the preliminary insulation pattern 320P disposed on the lateral side of the interlayer insulating layers 132m and the portion of the preliminary insulation pattern 320P disposed in the gate dielectric recess 300R. The preliminary charge inflow pattern 310P has a thickness that is sufficient to fill the gate dielectric recess 300R. For example, the maximum width of the preliminary charge inflow pattern 310P in the second direction (Y direction) is greater than the width of the gate dielectric pattern 300 in the second direction (Y direction). Hence, the preliminary charge inflow pattern 310P can fill the gate dielectric recess 300R.

Referring to FIG. 22, in an embodiment, the second channel hole CT2 is formed by removing at least a portion of the preliminary charge inflow pattern 310P and the preliminary insulation pattern 320P.

At least a portion of the preliminary charge inflow pattern 310P is etched so that portions of the preliminary charge inflow pattern 310P disposed in the gate dielectric recess 300R are spaced apart in the third direction (Z direction). At least a portion of the preliminary insulation pattern 320P is etched so that portions of the preliminary insulation pattern 320P disposed in the gate dielectric recess 300R are spaced apart in the third direction (Z direction). In an embodiment, a process for etching at least a portion of the preliminary charge inflow pattern 310P and the preliminary insulation pattern 320P includes using a dry etching method, but embodiments are not necessarily limited thereto.

Hence, the second channel hole CT2 is formed by etching at least a portion of the preliminary charge inflow pattern 310P and the preliminary insulation pattern 320P. In an embodiment, the second channel hole CT2 has a diameter that is substantially equal to that of the first channel hole CT1. For example, the width of the second channel hole CT2 in the second direction (Y direction) is substantially equal to the width of the first channel hole CT1 in the second direction.

While the second channel hole CT2 is being formed, the insulation patterns 320 are formed by separating portions of the preliminary insulation pattern 320P disposed in the gate dielectric recess 300R. Further, the charge inflow patterns 310 are formed by separating the portions of the preliminary charge inflow pattern 310P disposed in the gate dielectric recess 300R. For example, the insulation patterns 320 are spaced apart in the third direction (Z direction), and the charge inflow patterns 310 are spaced apart in the third direction (Z direction). As the second channel hole CT2 is being formed, lateral sides of the interlayer insulating layers 132m are exposed.

However, in some embodiments, without being necessarily limited thereto, portions of the preliminary insulation pattern 320P and portions of the preliminary charge inflow pattern 310P are not etched during a process of forming a second channel hole CT2. For example, similar to an embodiment of FIG. 8, the portion of the preliminary insulation pattern 320P disposed on the lateral side of the interlayer insulating layers 132m remains, and the second pattern portion 320E of the insulation pattern 320 is configured. In some embodiments, similar to an embodiment of FIG. 9, the portion of the preliminary insulation pattern 320P disposed on the lateral side of the interlayer insulating layers 132m remains to configure the second pattern portion 320E of the insulation pattern 320, and the portion of the preliminary charge inflow pattern 310P disposed on the lateral side of the interlayer insulating layers 132m remains to configure the second pattern portion 310E of the charge inflow pattern 310. For example, the charge inflow pattern 310 and/or the insulation pattern 320 extend in the third direction (Z direction). Further, the interlayer insulating layers 132m is not exposed.

The insulation pattern 320 surrounds at least a portion of the charge inflow pattern 310. For example, the insulation pattern 320 surrounds the upper side, the lower side, and the exterior side of the charge inflow pattern 310. For example, the insulation pattern 320 is disposed on the upper side of the charge inflow pattern 310, the lower side of the charge inflow pattern 310, and the exterior side of the charge inflow pattern 310.

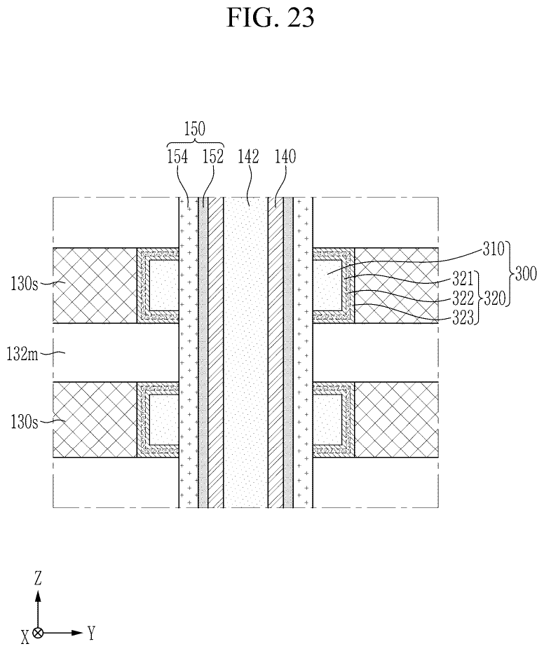

Referring to FIG. 23, in an embodiment, the channel structure CH is formed in the second channel hole CT2. The dielectric layer 150, the channel layer 140, and the core insulation layer 142 are sequentially stacked in the second channel hole CT2. During a process of forming the dielectric layer 150, the ferroelectric layer 154 and the channel insulation layer 152 are sequentially stacked to form the dielectric layer 150. However, in some embodiment, without being necessarily limited thereto, similar to an embodiment shown in FIG. 12, the ferroelectric material is formed as multiple layers.

Hence, the ferroelectric layer 154 overlaps the gate dielectric pattern 300 in the radial direction of the channel structure CH. For example, one portion of the ferroelectric layer 154 overlaps the gate dielectric pattern 300 in the radial direction of the channel structure CH, and another portion of the ferroelectric layer 154 overlaps the interlayer insulating layers 132m in the radial direction of the channel structure CH. The ferroelectric layer 154 directly contacts the gate dielectric pattern 300. For example, the exterior side of the ferroelectric layer 154 directly contacts the gate dielectric patterns 300 that are spaced apart and disposed in the third direction (Z direction).

The ferroelectric layer 154, the channel insulation layer 152 and the channel layer 140 have a conformal shape with a predetermined thickness in the first channel hole CT1. The ferroelectric layer 154, the channel insulation layer 152 and the channel layer 140 cover the internal sidewall and the bottom side of the second channel hole CT2. The inside of the second channel hole CT2 is not completely filled by the dielectric layer 150 and the channel layer 140. The portion of the second channel hole CT2 not filled by the dielectric layer 150 and the channel layer 140 is filled by the core insulation layer 142. In addition, a channel pad is formed on the dielectric layer 150, the channel layer 140, and the core insulation layer 142.

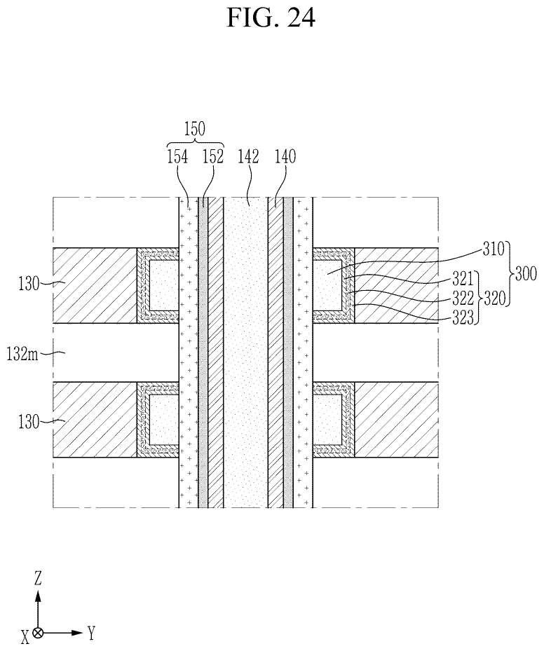

Referring to FIG. 24, in an embodiment, the sacrificial insulation layers 130s are removed, and the gate electrodes 130 are formed in the space from which the sacrificial insulation layers 130s were removed. For example, the sacrificial insulation layers 130s are removed by using an etching process, and the gate electrodes 130 are formed by depositing a metal, such as one of tungsten (W), copper (Cu), or aluminum (Al). The gate electrodes 130 include a lower gate electrode 130L, memory cell gate electrodes 130M, and an upper gate electrode 130U that are sequentially disposed on the second substrate 110. The lower gate electrode 130L is a gate electrode of the ground selecting transistor, the memory cell gate electrodes 130M configure a memory cell, and the upper gate electrode 130U is a gate electrode of the string selecting transistor.

An electronic system that includes a semiconductor device according to an embodiment will now be described with reference to FIG. 25.

FIG. 25 shows an electronic system that includes a semiconductor device according to an embodiment.

As shown in FIG. 25, in an embodiment, an electronic system 1000 includes a semiconductor device 1100 and a controller 1200 electrically connected to the semiconductor device 1100. The electronic system 1000 may be a storage device that includes one or more semiconductor devices 1100, or an electronic device that includes the storage device. For example, the electronic system 1000 is a solid state drive (SSD) device that includes one or more semiconductor devices 1100, a universal serial bus (USB), a computing system, a medical device, or a communication device.

The semiconductor device 1100 is a non-volatile memory device, such as a NAND flash memory device described with reference to FIG. 1 to FIG. 14. The semiconductor device 1100 includes a first structure 1100F and a second structure 1100S disposed on the first structure 1100F. In an embodiment, the first structure 1100F is disposed near the second structure 1100S. The first structure 1100F is a peripheral circuit structure that includes a decoder circuit 1110, a page buffer 1120, and a logic circuit 1130. The second structure 1100S is a memory cell structure that includes a bit line BL, a common source line CSL, a word line WL, first and second gate upper lines UL1 and UL2, first and second gate lower lines LL1 and LL2, and a memory cell string CSTR between the bit line BL and the common source line CSL.

Regarding the second structure 1100S, the respective memory cell strings CSTR include lower transistors LT1 and LT2 disposed near the common source line CSL, upper transistors UT1 and UT2 disposed near the bit line BL, and memory cell transistors MCT disposed between the lower transistors LT1 and LT2 and the upper transistors UT1 and UT2. The number of the lower transistors LT1 and LT2 and the number of the upper transistors UT1 and UT2 can change in many ways depending on embodiments.

In an embodiment, the lower transistors LT1 and LT2 include ground selecting transistors, and the upper transistors UT1 and UT2 include string selecting transistors. The first and second gate lower lines LL1 and LL2 are gate electrodes of the lower transistors LT1 and LT2, respectively. The word line WL is a gate electrode of the memory cell transistor MCT, and the gate upper lines UL1 and UL2 are gate electrodes of the upper transistors UT1 and UT2, respectively.

The common source line CSL, the first and second gate lower lines LL1 and LL2, the word line WL, and the first and second gate upper lines UL1 and UL2 are electrically connected to the decoder circuit 1110 through a first connecting wire 1115 that extends to the second structure 1100S from the first structure 1100F. The bit line BL is electrically connected to the page buffer 1120 through a second connecting wire 1125 that extends to the second structure 1100S from the first structure 1100F.

Regarding the first structure 1100F, the decoder circuit 1110 and the page buffer 1120 perform a control operation on at least one of the memory cell transistors MCT. The decoder circuit 1110 and the page buffer 1120 are controlled by the logic circuit 1130. The semiconductor device 1100 communicates with the controller 1200 through an input/output pad 1101 electrically connected to the logic circuit 1130. The input/output pad 1101 is electrically connected to the logic circuit 1130 through an input/output connecting wire 1135 that extends to the second structure 1100S from the first structure 1100F.

The controller 1200 includes a processor 1210, a NAND controller 1220, and a host interface 1230. According to an embodiment, the electronic system 1000 includes semiconductor devices 1100, and the controller 1200 controls the semiconductor devices 1100.

The processor 1210 controls a general operation of the electronic system 1000 that includes the controller 1200. The processor 1210 is operable according to predetermined firmware, and controls the NAND controller 1220 to access the semiconductor device 1100. The NAND controller 1220 includes a NAND interface 1221 that processes communication with the semiconductor device 1100. Control instructions that control the semiconductor device 1100, data to be written to the memory cell transistor MCT of the semiconductor device 1100, and data to be read from the memory cell transistor MCT of the semiconductor device 1100, are transmitted through the NAND interface 1221. The host interface 1230 provides a communication function between the electronic system 1000 and an external host. When receiving a control instruction from the external host through the host interface 1230, the processor 1210 controls the semiconductor device 1100 in response to the control instruction.

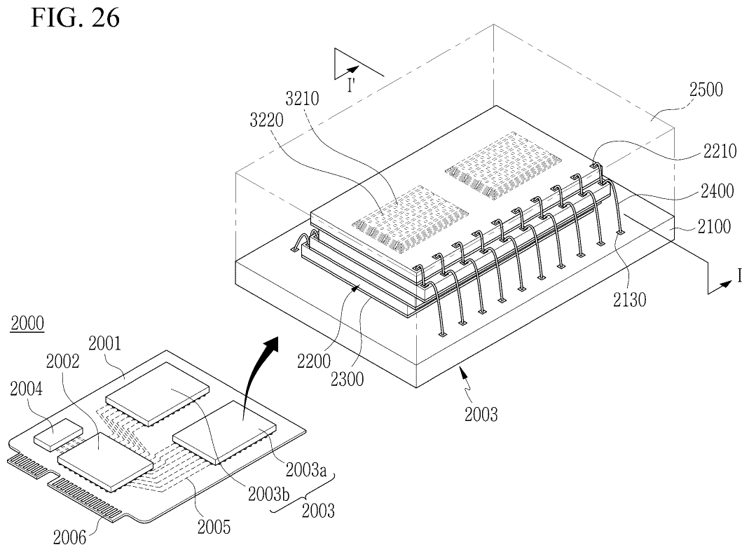

FIG. 26 is a perspective view of an electronic system that includes a semiconductor device according to an embodiment.

As shown in FIG. 26, in an embodiment, an electronic system 2000 includes a main substrate 2001, a controller 2002 mounted on the main substrate 2001, one or more semiconductor packages 2003, and a DRAM 2004. The semiconductor package 2003 and the DRAM 2004 are connected to the controller 2002 by a wire pattern 2005 formed on the main substrate 2001.

The main substrate 2001 includes a connector 2006 that includes pins that can combine to the external host. Regarding the connector 2006, the number and arrangement of the pins can be modifiable by a communication interface between the electronic system 2000 and the external host. In an embodiment, the electronic system 2000 communicates with the external host according to an interface, such as one of the universal serial bus (USB), a peripheral component interconnect express (PCI-Express), a serial advanced technology attachment (SATA), or an M-Phy for universal flash storage (UFS). In an embodiment, the electronic system 2000 is operable by a power voltage supplied from the external host through the connector 2006. The electronic system 2000 further includes a power management integrated circuit (PMIC) that provides the power voltage supplied by the external host to the controller 2002 and the semiconductor package 2003.

The controller 2002 can write data to the semiconductor package 2003, read data from the semiconductor package 2003, or increase an operation speed of the electronic system 2000.

The DRAM 2004 is a buffer memory that reduces a speed difference between the semiconductor package 2003, which is a data storage space, and the external host. The DRAM 2004 in the electronic system 2000 can also function as a cache memory, and provides a space that temporarily stores data in an operation of controlling the semiconductor package 2003. When the electronic system 2000 includes the DRAM 2004, the controller 2002 further includes a DRAM controller that controls the DRAM 2004, in addition to an NAND controller that controls the semiconductor package 2003.

The semiconductor package 2003 includes first and second semiconductor packages 2003a and 2003b that are spaced apart from each other. The first and second semiconductor packages 2003a and 2003b are each a semiconductor package that includes semiconductor chips 2200. The first and second semiconductor packages 2003a and 2003b each include a package substrate 2100, a semiconductor chip 2200 disposed on the package substrate 2100, an adhesive layer 2300 disposed on the lower side of the semiconductor chip 2200, a connection structure 2400 that electrically connects the semiconductor chip 2200 and the package substrate 2100, and a molding layer 2500 that covers the semiconductor chip 2200 and the connection structure 2400 on the package substrate 2100.

The package substrate 2100 is a printed circuit board that includes a package upper pad 2130. Each the semiconductor chip 2200 includes an input/output pad 2210. The input/output pad 2210 corresponds to the input/output pad 1101 of FIG. 25. The respective semiconductor chips 2200 each include a gate stacking structure 3210 and a channel structure 3220. The respective semiconductor chips 2200 each include a semiconductor device described with reference to FIG. 1 to FIG. 14.

In an embodiment, the connection structure 2400 is a bonding wire that electrically connects the input/output pad 2210 and the package upper pad 2130. Therefore, regarding the respective first and second semiconductor packages 2003a and 2003b, the respective semiconductor chips 2200 are electrically connected to each other by a bonding wire method, and are electrically connected to the package upper pad 2130 of the package substrate 2100. According to an embodiment, regarding the respective first and second semiconductor packages 2003a and 2003b, the semiconductor chips 2200 are electrically connected to each other by a connection structure that includes a through silicon via (TSV) instead of the bonding-wire-type connection structure 2400.

In an embodiment, the controller 2002 and the semiconductor chip 2200 are included into one package. For example, the controller 2002 and the semiconductor chip 2200 are mounted on an interposer substrate that differs from the main substrate 2001, and the controller 2002 is connected to the semiconductor chip 2200 by a wire formed on the interposer substrate.

FIG. 27 and FIG. 28 are cross-sectional views of a semiconductor package according to an embodiment. FIG. 27 and FIG. 28 show an embodiment of the semiconductor package 2003 of FIG. 26, and conceptually show a region of the semiconductor package 2003 of FIG. 26 with respect to a cutting line I-I′.

Referring to FIG. 27, in an embodiment, the package substrate 2100 is a printed circuit board in the semiconductor package 2003. The package substrate 2100 includes a package substrate body 2120, a package upper pad 2130 disposed on an upper side of the package substrate body 2120, a lower pad 2125 disposed on a lower side of the package substrate body 2120 and exposed through the lower side, and an internal wire 2135 that electrically connects the upper pad 2130 and the lower pad 2125 in the package substrate body 2120. The upper portion pad 2130 is electrically connected to the connection structure 2400. The lower pad 2125 is connected to the wire pattern 2005 of the main substrate 2001 of the electronic system 2000 through a conductive connector 2800 as shown in FIG. 27.

The semiconductor chip 2200 includes a semiconductor substrate 3010 and a first structure 3100 and a second structure 3200 that are sequentially stacked on the semiconductor substrate 3010. The first structure 3100 includes a peripheral circuit region that includes a peripheral wire 3110. The second structure 3200 includes a common source line 3205, a gate stacking structure 3210 disposed in the common source line 3205, a channel structure 3220 and a separation structure 3230 that penetrate the gate stacking structure 3210, a bit line 3240 electrically connected to the channel structure 3220, and a gate connecting wire that electrically connects the word line WL of FIG. 25 to the gate stacking structure 3210.

Regarding the semiconductor chip 2200 of the semiconductor device, the charge inflow pattern 310 is disposed on one side of the ferroelectric layer 154, and the insulation pattern 320 surrounds at least a portion of the charge inflow pattern 310. Hence, when a voltage is applied to the gate electrodes 130, an electric field is easily generated in the charge inflow pattern 310 according to the dopant concentration. Hence, the operating voltage that generates the residual polarization in the ferroelectric layer 154 can be reduced, and a reliability of the semiconductor device 10 is increased.

The respective semiconductor chips 2200 include a penetrating wire 3245 electrically connected to the peripheral wire 3110 of the first structure 3100 and that extends into the second structure 3200. The penetrating wire 3245 penetrates the gate stacking structure 3210 and is further arranged outside the gate stacking structure 3210. The respective semiconductor chips 2200 further include an input/output connecting wire 3265 electrically connected to the peripheral wire 3110 of the first structure 3100 and that extends into the second structure 3200, and an input/output pad 2210 electrically connected to the input/output connecting wire 3265.

In the embodiment, the semiconductor chips 2200 are electrically connected to each other by the connection structure 2400 in a bonding wire form in the semiconductor package 2003. In an embodiment, the semiconductor chips 2200 or portions thereof are electrically connected by a connection structure that includes a through silicon via (TSV).

Referring to FIG. 28, in an embodiment, regarding the semiconductor package 2003A, the respective semiconductor chips 2200 include a semiconductor substrate 4010, a first structure 4100 disposed on the semiconductor substrate 4010, and a second structure 4200 bonded to the first structure 4100 by a wafer bonding method.

The first structure 4100 includes a peripheral circuit region that includes a peripheral wire 4110 and a first junction structure 4150. The second structure 4200 includes a common source line 4205, a gate stacking structure 4210 disposed between the common source line 4205 and the first structure 4100, a channel structure 4220 and a separation structure 4230 that penetrate the gate stacking structure 4210, and a second junction structure 4250 electrically connected to the channel structure 4220 and the word line WL of FIG. 25 of the gate stacking structure 4210. For example, the second junction structure 4250 is electrically connected to the channel structure 4220 and the word line WL through the gate connecting wire electrically connected to the bit line 4240 and the word line WL electrically connected to the channel structure 4220. The first junction structure 4150 of the first structure 4100 and the second junction structure 4250 of the second structure 4200 directly contact each other and are bonded to each other. A bonded portion of the first junction structure 4150 and the second junction structure 4250 includes, for example, copper (Cu).

Regarding the semiconductor chip 2200 of the semiconductor device, the charge inflow pattern 310 is disposed on one side of the ferroelectric layer 154, and the insulation pattern 320 surrounds at least a portion of the charge inflow pattern 310. Hence, when a voltage is applied to the gate electrodes 130, an electric field is easily generated in the charge inflow pattern 310 according to the dopant concentration. Hence, an operating voltage that generates the residual polarization in the ferroelectric layer 154 is reduced, and a reliability of the semiconductor device 10 is increased.

The respective semiconductor chips 2200 further include an input/output pad 2210 and an input/output connecting wire 4265 disposed on a lower portion of the input/output pad 2210. The input/output connecting wire 4265 is electrically connected to a portion of the second junction structure 4250.

In an embodiment, the semiconductor chips 2200 are electrically connected to each other by the connection structure 2400 in a bonding wire form in the semiconductor package 2003. In an embodiment, the semiconductor chips 2200 or portions thereof are electrically connected by a connection structure that includes a through silicon via.

While embodiments of this disclosure have been described in connection with the accompanying drawings, it is to be understood that embodiments of the disclosure is not limited to disclosed embodiments, but, on the contrary, are intended to cover various modifications and equivalent arrangements included within the spirit and scope of the appended claims.

### DESCRIPTION OF SYMBOLS

100: cell region
200: circuit region
102: cell array region
104: contact region
110: second substrate
120: gate stacking structure
CH: channel structure
130: gate electrodes
132m: interlayer insulating layers
300: gate dielectric pattern
310: charge inflow pattern
320: insulation pattern

What is claimed is:

1. A semiconductor device, comprising:
a substrate;
a gate stacking structure that includes interlayer insulating layers and gate electrodes that are alternately stacked on the substrate;
a channel structure that penetrates the gate stacking structure and extends in a first direction, and includes a channel layer connected to the substrate and a ferroelectric layer that surrounds the channel layer;
a charge inflow pattern disposed on a lateral side of the ferroelectric layer and spaced apart in the first direction; and
an insulation pattern disposed between the charge inflow pattern and the gate electrodes and that surrounds an exterior side, a lower side, and an upper side of the charge inflow pattern.

2. The semiconductor device of claim 1, wherein
the insulation pattern is further disposed between the charge inflow pattern and the interlayer insulating layers.

3. The semiconductor device of claim 1, wherein
the insulation pattern comprises a first portion, a second portion, and a third portion, and nitrogen is doped intro each of the first to third portions, and
a concentration of nitrogen doped in at least one of the first to third portions differs from a concentration of nitrogen doped in at least another of the first to third portions.

4. The semiconductor device of claim 3, wherein
the insulation pattern comprises a portion in which the concentration of nitrogen monotonically decreases with increasing distance from the charge inflow pattern.

5. The semiconductor device of claim 3, wherein
the first portion surrounds the exterior side, the lower side, and the upper side of the charge inflow pattern,
the second portion surrounds an exterior side, a lower side, and an upper side of the first portion, and
the third portion surrounds an exterior side, a lower side, and an upper side of the second portion.

6. The semiconductor device of claim 1, wherein the insulation pattern comprises:
a first insulation pattern that surrounds at least a portion of the charge inflow pattern,
a second insulation pattern that surrounds the first insulation pattern, and
a third insulation pattern that surrounds the second insulation pattern, wherein
the second insulation pattern includes a material that differs from that of the first insulation pattern and the third insulation pattern.

7. The semiconductor device of claim 6, wherein
the second insulation pattern comprises at least one of SiN, SiON, SiOCN, or SiCN, and
the first insulation pattern and the third insulation pattern include SiO₂.

8. The semiconductor device of claim 1, wherein
the charge inflow pattern comprises SiN.

9. The semiconductor device of claim 8, wherein
the charge inflow pattern overlaps the gate electrodes in a radial direction of the channel structure, but does not overlap the interlayer insulating layers in the radial direction of the channel structure.

10. The semiconductor device of claim 1, wherein
a width of the charge inflow pattern in the first direction is less than a width of the gate electrodes in the first direction.

11. The semiconductor device of claim 1, wherein
a thickness of the charge inflow pattern in the radial direction from a center of the channel structure is from 0.5 nm to 20 nm.

12. The semiconductor device of claim 1, wherein the charge inflow pattern comprises:
first pattern portions disposed between the ferroelectric layer and the gate electrodes, and
second pattern portions disposed between the ferroelectric layer and the interlayer insulating layers and between the first pattern portions.

13. The semiconductor device of claim 12, wherein
a thickness of the second pattern portion in the radial direction of the channel structure is less than a thickness of the charge inflow pattern in the radial direction of the channel structure.

14. The semiconductor device of claim 1, wherein the ferroelectric layer comprises:
a first ferroelectric layer disposed on an exterior side of the channel layer, a second ferroelectric layer that surrounds the first ferroelectric layer, and an interface inserting film disposed between the first ferroelectric layer and the second ferroelectric layer, wherein
at least one of the first ferroelectric layer and the second ferroelectric layer includes at least one of HfO₂, HfZnO, HfSiO, HfSiON, HfTaO, HfTiO, HfZrO, or combinations thereof.

15. The semiconductor device of claim 14, wherein
the first ferroelectric layer, the second ferroelectric layer, and the interface inserting film each include HfSiO, and
a concentration of Si in the interface inserting film is greater than a concentration of Si in the first ferroelectric layer or a concentration of Si in the second ferroelectric layer.

16. A semiconductor device, comprising:
a substrate;
a gate stacking structure that includes interlayer insulating layers and gate electrodes that are alternately stacked on the substrate;
a channel structure that penetrates the gate stacking structure and extends in a first direction, and includes a channel layer connected to the substrate and a ferroelectric layer that surrounds the channel layer;
a charge inflow pattern disposed between the ferroelectric layer and the gate electrodes; and
an insulation pattern disposed between the charge inflow pattern and the gate electrodes and between the charge inflow pattern and the interlayer insulating layers, and into which nitrogen is doped, wherein
a concentration of nitrogen in at least a portion of the insulation pattern decreases with increasing distance from the charge inflow pattern.

17. The semiconductor device of claim 16, wherein
the charge inflow pattern overlaps the gate electrodes in a radial direction of the channel structure, but does not overlap the interlayer insulating layers in the radial direction of the channel structure.

18. An electronic system, comprising:
a main substrate;
a semiconductor device disposed on the main substrate; and
a controller that is electrically connected to the semiconductor device on the main substrate,
wherein the semiconductor device includes:
a peripheral circuit region,
a cell region that includes an input/output connecting wire that is electrically connected to the peripheral circuit region, and
an input/output pad that is electrically connected to the input/output connecting wire that extends into the cell region,
and the cell region includes:
a substrate,
a gate stacking structure that includes interlayer insulating layers and gate electrodes that are alternately stacked on the substrate,
a channel structure that penetrates the gate stacking structure and extends in a first direction, and includes a channel layer connected to the substrate and a ferroelectric layer that surrounds the channel layer,
a charge inflow pattern disposed on a lateral side of the ferroelectric layer and spaced apart in the first direction, and
an insulation pattern disposed between the charge inflow pattern and the gate electrodes and that surrounds an exterior side, a lower side, and an upper side of the charge inflow pattern.

19. The electronic system of claim 18, wherein the insulation pattern comprises:
a first portion that surrounds the exterior side, the lower side, and the upper side of the charge inflow pattern, and
a second portion that surrounds an exterior side, a lower side, and an upper side of the first portion,
wherein the first portion and the second portion each include an insulating material into which nitrogen is doped, and
a concentration of nitrogen doped into the second portion is greater than a concentration of nitrogen doped into the first portion.

20. The electronic system of claim 18, wherein
a width of the charge inflow pattern in the first direction is less than widths of the gate electrodes in the one direction.
